(19) United States
(12) Patent Application Publication
(10) Pub. No.: US 2026/0215005 A1
(43) Pub. Date: Jul. 23, 2026

(54) SEMICONDUCTOR DEVICE AND METHOD OF MANUFACTURING THE SAME

(71) Applicant: Taiwan Semiconductor Manufacturing Company, Ltd., Hsinchu (TW)

(72) Inventors: Tzu-Jui Wang, Fengshan City (TW); Shih-Min Huang, Hsinchu County (TW); Ming-Chieh Hsu, Hsinchu City (TW); Kuo-Chin Huang, Yilan City (TW); Chi-Hsien Chung, New Taipei City (TW); Chia-Chi Hsiao, Tianzhong Township (TW)

(21) Appl. No.: 19/241,594

(22) Filed: Jun. 18, 2025

Related U.S. Application Data
(60) Provisional application No. 63/748,530, filed on Jan. 23, 2025.

(51) Int. Cl. H10F 30/222; H10F 71/00; H10F 77/1226

(52) U.S. Cl. CPC H10F 30/222; H10F 71/1215; H10F 77/1227

(57) ABSTRACT

Various embodiments of the present disclosure are directed towards a device. The device includes a substrate comprising a first material. An absorption structure is on a surface of the substrate and comprises a second material having a smaller bandgap than the first material. The absorption structure has a first doping concentration of a first doping type. The first doping concentration of the absorption structure is greater than a doping concentration of a region of the substrate abutting the absorption structure. A first well region is in the substrate and offset from the absorption structure. The first well region has a second doping type different from the first doping type. A second well region is in the substrate and arranged between the first well region and the absorption structure. The second well region has the first doping type.

### RELATED APPLICATIONS

This Application claims the benefit of U.S. Provisional Application No. 63/748,530, filed on Jan. 23, 2025, the contents of which are hereby incorporated by reference in their entirety.

### BACKGROUND

Image sensors are solid-state devices that are configured to convert incoming light into an electrical signal. The electrical signal is then provided to a processor that can convert the electrical signal to data that can be stored and/or viewed by a user. Integrated chips with image sensors are used in a wide range of modern-day electronic devices, such as cell phones, cameras, medical devices, etc.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of various features may be arbitrarily increased or reduced for clarity of discussion.

FIG. 1 illustrates a cross-sectional view of some embodiments of an image sensor including a photodetector that comprises an absorption structure with a relatively high doping concentration.

FIGS. 2A-2B illustrate graphs showing various embodiments of doping profiles of the absorption structure of FIG. 1.

FIG. 3 illustrates a cross-sectional view of some other embodiments of an image sensor including a photodetector that comprises an absorption structure with a relatively high doping concentration.

FIGS. 4A-4B illustrate cross-sectional views of some other different embodiments of the image sensor of FIG. 1.

FIGS. 5A-5C illustrate cross-sectional views of some other different embodiments of the image sensor of FIG. 1.

FIGS. 6A-6D illustrate cross-sectional views of some other different embodiments of the image senor of FIG. 5A.

FIGS. 7A-7F illustrate graphs showing various embodiments of doping profiles of the absorption structure of FIG. 6D.

FIGS. 8A-8B illustrate cross-sectional views of some other different embodiments of the image sensor of FIG. 4B.

FIGS. 9A-9B illustrate cross-section views of some other embodiments of an image sensor including a photodetector that comprises an absorption structure with a relatively high doping concentration.

FIGS. 10A-10H illustrates cross-sectional views of some other different embodiments of the image senor of FIG. 1.

FIGS. 11A-11D illustrate cross-sectional views of some other different embodiments of the image sensor of FIG. 1, in which the image sensor comprises a first integrated circuit (IC) chip and a second IC chip.

FIGS. 12-20 illustrate a series of cross-sectional views of some embodiments of a method of forming an image sensor including a photodetector that comprises an absorption structure with a relatively high doping concentration.

FIGS. 21-24 illustrate a series of cross-sectional views of some other embodiments of a method of forming an image sensor including a photodetector that comprises an absorption structure with a relatively high doping concentration.

FIG. 25 illustrates a block diagram of some embodiments of a method of forming an image sensor including a photodetector that comprises an absorption structure with a relatively high doping concentration.

FIGS. 26-32 illustrate a series of cross-sectional views of further embodiments of a method of forming an image sensor including a photodetector that comprises an absorption structure with a relatively high doping concentration.

FIGS. 33-36 illustrate a series of cross-sectional views of yet further embodiments of a method of forming an image sensor including a photodetector that comprises an absorption structure with a relatively high doping concentration.

FIG. 37 illustrates a block diagram of some other embodiments of a method of forming an image sensor including a photodetector that comprises an absorption structure with a relatively high doping concentration.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

Image sensor integrated chips may comprise photodetectors configured to detect short wavelength infrared (SWIR) radiation. The photodetectors may, for example, be single photon avalanche diodes (SPADs) for indirect time-of-flight (iToF) depth sensing or some other suitable application. Such a photodetector may comprise an absorption structure on or recessed into a substrate, as well as an avalanche region in the substrate and under or arranged on sides of the absorption structure. The substrate may comprise silicon, and the absorption structure may comprise germanium. Germanium has a small bandgap compared to silicon and therefore has a higher absorption for SWIR radiation compared to silicon.

The absorption structure comprising germanium increases a quantum efficiency (QE) of the photodetector for SWIR radiation compared to a silicon-based photodetector. However, the germanium absorption structure may result in high dark current, which may result in a high dark current rate (DCR) (e.g., greater than 1 megahertz (MHz)) and may hence negatively impact performance. The high dark current may occur due to: interface states between the substrate and the germanium absorption structure; crystalline defects in the germanium absorption structure; and a high intrinsic carrier concentration in the germanium absorption structure. Due to germanium's smaller bandgap (e.g., approximately 0.66 eV), intrinsic carrier concentration in germanium is higher than that of silicon. As a result, thermal excitation (e.g., at room temperature), even in the absence of light, can generate electron-hole pairs in the germanium absorption structure that contribute to the high dark current.

The absorption structure may comprise intrinsic or lightly doped germanium. For example, a bulk of the absorption structure may be lightly doped (e.g., having a doping concentration less than approximately 1×10¹⁵ atoms per cubic centimeter (atoms/cm³)) with p-type dopants. The light doping may assist in passivating crystalline defects, while still preserving space in the absorption structure for additional doped regions. Further, a p-type guard ring may be formed along a periphery of the absorption structure, where the p-type guard ring may passivate crystalline defects and interface states to suppress dark current. However, the light doping of the bulk of the absorption structure or the p-type guard ring at the peripheral region, individually or in combination with one another, does not sufficiently decrease issues due to interface states between the substrate and the germanium absorption structure and/or decrease issues due to the high intrinsic carrier concentration of germanium. As a result, the photodetector has high dark current and may have decreased accuracy in depth sensing applications.

Various embodiments of the present disclosure are directed towards an image sensor having a photodetector that comprises an absorption structure with a relatively high doping concentration to reduce dark current. The absorption structure is arranged on or within a substrate. The substrate comprises a first material (e.g., silicon) and the absorption structure comprises a second material (e.g., germanium) having a smaller bandgap than the first material. A first avalanche well is arranged in the substrate and an avalanche region is arranged between the first avalanche well and the absorption structure. At least a majority of a volume (e.g., at least 50% of the volume) of a bulk of the absorption structure is highly doped (e.g., doping concentration greater than approximately 2×10¹⁸ atoms/cm³) with p-type dopants. As a result, the formation (e.g., thermal generation) of free charge carriers (e.g., free electrons) in the absorption structure that lead to dark current is reduced. Further, by virtue of absorption structure being highly doped with the p-type dopants, the formation of other regions (e.g., a p-type guard ring) in the absorption structure and/or the substrate to suppress dark current may be omitted, thereby decreasing manufacturing complexity. Therefore, the absorption structure being highly doped with p-type dopants decreases DCR (e.g., to approximately 1 MHz or less) while maintaining photon-detection efficiency (PDE).

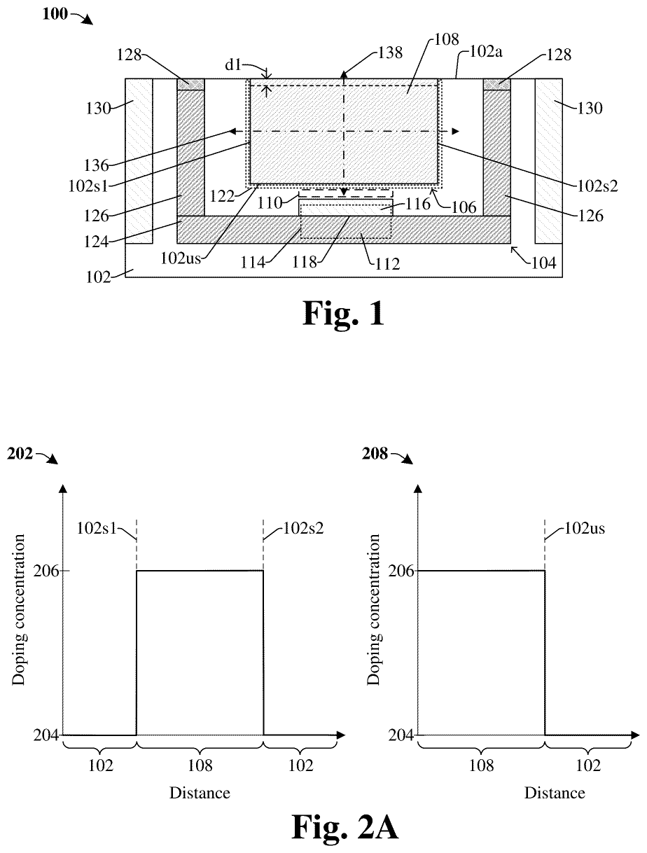

FIG. 1 illustrates a cross-sectional view 100 of some embodiments of an image sensor including a photodetector that comprises an absorption structure with a relatively high doping concentration.

The image sensor includes a substrate 102. In some embodiments, the substrate 102 has one or more surfaces defining a recess 106 that extends into a first surface 102a of the substrate 102. For example, the substrate 102 comprises inner sidewalls 102s1, 102s2 and an upper surface 102us defining the recess 106. A photodetector 104 comprises an absorption structure 108 and an avalanche region 114 in the substrate 102. The absorption structure 108 is disposed in the recess 106. In some embodiments, the absorption structure 108 directly contacts the one or more surfaces of the substrate 102 defining the recess 106. In some embodiments, a bulk of the substrate 102 is intrinsic (e.g., intrinsic silicon) or is lightly doped with first dopants having a first doping type (e.g., p-type). Lightly doped may, for example, correspond to a doping concentration equal to or less than approximately 1×10¹⁵ atoms/cm³, equal to or less than approximately 1×10¹⁶ atoms/cm³, equal to or less than approximately 5×10¹⁶ atoms/cm³, or some other suitable value.

A lateral connection region 124 is arranged in the substrate 102 below the absorption structure 108. A vertical connection region 126 is arranged in the substrate 102 on opposing sides of the absorption structure 108 and over outer edges of the lateral connection region 124. In some embodiments, the vertical connection region 126 may be referred to as a vertical well region. A first contact region 128 is arranged in the substrate 102 over the vertical connection region 126. A first avalanche well 112 is arranged in the substrate 102 under the absorption structure 108. In some embodiments, the first avalanche well 112 is a segment of the lateral connection region 124 arranged in a middle region of the lateral connection region 124. In yet further embodiments, the lateral connection region 124 continuously laterally extends around the first avalanche well 112. A second avalanche well 116 is arranged in the substrate 102. The second avalanche well 116 is disposed between the first avalanche well 112 and the absorption structure 108. The second avalanche well 116 comprises the first doping type (e.g., p-type). The first avalanche well 112, the lateral connection region 124, the vertical connection region 126, and the first contact region 128 comprise a second doping type (e.g., n-type) opposite the first doping type (e.g., p-type). An isolation structure 130 is arranged in the substrate on opposing sides of the absorption structure 108.

The photodetector 104 may, for example, be a SPAD, an avalanche photodiode (APD), or the like. The avalanche region 114 is arranged in the substrate 102 and is formed by a PN junction 118 at which the first avalanche well 112 and the second avalanche well 116 meet. The avalanche region 114 corresponds to a region at which charge carriers, generated from incident electromagnetic radiation that strikes the absorption structure 108, are multiplied by the avalanche effect. In some embodiments, a region 110 of the substrate 102 disposed between the absorption structure 108 and the avalanche region 114 may be configured as a channel region between the PN junction 118 and the absorption structure 108. In various embodiments, the region 110 comprises intrinsic silicon or silicon lightly doped with the first doping type (e.g., p-type).

The substrate 102 comprises a first material and the absorption structure 108 comprises a second material different than the first material. In some embodiments, the first material, may for example, be or comprise silicon or some other suitable material and the second material may, for example, be or comprise germanium, a germanium-tin alloy, or some other suitable material. The absorption structure 108 has a higher absorption coefficient for target radiation (e.g., SWIR radiation) than the substrate 102. In some embodiments, the absorption structure 108 may have the higher absorption coefficient because a bandgap of the second material (e.g., germanium) is smaller than that of the first material (e.g., silicon). The target radiation may, for example, be or comprise SWIR radiation and may include radiation with a wavelength greater than approximately 1,000 nanometers (nm), within a range of approximately 1,000 to 3,000 nm, or some other suitable value. Further, an upper surface of the absorption structure 108 may be aligned with the first surface 102a of the substrate 102. In some embodiments, the upper surface of the absorption structure 108 may be disposed at a first depth d1 below the first surface 102a of the substrate 102. The first depth d1 may, for example, be within a range of approximately 30 to 50 nm or some other suitable value.

In some embodiments, the absorption structure 108 meets or contacts the substrate 102 at an interface region 122. The interface region 122 may, for example, be a Si-Ge interface region and is defined where outer sidewalls and a lower surface of the absorption structure 108 meet inner sidewalls 102s1, 102s2 and the upper surface 102us, respectively, of the substrate 102. In various embodiments, the interface region 122 comprises a Ge-Si alloy having a lattice constant between a first lattice constant of germanium and a second lattice constant of silicon. In further embodiments, a thickness of the interface region 122 is within a range of 0.1 to 25 nm or some other suitable value.

In various embodiments, the absorption structure 108 is heavily doped with first dopants (e.g., boron, gallium, etc.) having the first doping type (e.g., p-type). For example, at least a majority of a volume (e.g., at least 50% of the volume) of a bulk of the absorption structure 108 is heavily doped with the first doping type. Heavily doped may, for example, correspond to a doping concentration greater than approximately 2×10¹⁸ atoms/cm³ or some other suitable value. In some embodiments, the doping concentration of the absorption structure 108 is greater than that of the first avalanche well 112, the vertical connection region 126, the lateral connection region 124, and/or the second avalanche well 116.

During operation of the image sensor, the photodetector 104 may be biased by support circuitry (not shown). For example, the first contact region 128 and the absorption structure 108 may be biased by the support circuitry. In some embodiments, the photodetector 104 is biased above an avalanche breakdown voltage. While the photodetector 104 is biased, target incident radiation (e.g., IR radiation, SWIR radiation, etc.) that is absorbed at the absorption structure 108 causes an electron-hole pair to be generated in the absorption structure 108. A released charge carrier (e.g., released electron) from the generated electron-hole pair drifts through the region 110 to the avalanche region 114. The released charge carrier (e.g., released electron) is accelerated at the avalanche region 114 to a kinetic energy that overcomes ionization energy of the substrate 102 and creates further electron-hole pairs in the avalanche region 114. This leads to an avalanche current that can be measured.

The absorption structure 108 having the second material (e.g., germanium) with the smaller bandgap of the substrate 102 increases quantum efficiency for the target radiation (e.g., SWIR radiation). However, the second material (e.g., germanium) can be prone to high dark current, for example, due to the smaller bandgap an intrinsic carrier concentration of the absorption structure 108 is greater than an intrinsic carrier concentration of the substrate 102. In some embodiments, doping aside, the intrinsic carrier concentration of the absorption structure 108 is approximately 2.5×10¹³ atoms/cm³ and the intrinsic carrier concentration of the substrate 102 is approximately 1.1×10¹⁰ atoms/cm³. By virtue of the absorption structure 108 being heavily doped (e.g., a doping concentration greater than approximately 2×10¹⁸ atoms/cm³) with the first doping type (e.g., p-type), the absorption structure 108 is rich in holes that facilitate reducing dark current. For example, the absorption structure 108 being hole rich increases a likelihood that the holes will recombine with free electrons, that were generated from thermal excitation, before the free electron could diffuse from the absorption structure 108 and contribute to dark current. As a result, the absorption structure 108 being highly doped with the first doping type (e.g., p-type) decreases DCR (e.g., to approximately 1 MHz or less) in the photodetector 104 while maintaining PDE. This increases an overall performance of the image sensor.

The absorption structure 108 has a first doping concentration of first dopants (e.g., boron, gallium, etc.) of the first doping type (e.g., p-type). The first doping concentration may, for example, be greater than approximately 2×10¹⁸ atoms/cm³, equal to or greater than approximately 1×10¹⁹ atoms/cm³, within a range of approximately 2×10¹⁸ to 5×10²⁰ atoms/cm³, or some other suitable value. In various embodiments, the first doping concentration of the absorption structure 108 being greater than approximately 2×10¹⁸ atoms/cm³ facilitates reducing dark current in the photodetector 104. In yet further embodiments, the first doping concentration of the absorption structure 108 being less than approximately 5×10²⁰ atoms/cm³ facilities reduction of dark current while maintaining or increasing PDE.

In various embodiments, the absorption structure 108 is uniformly doped across the volume of the absorption structure 108, such that the doping concentration of the first doping type across the volume of the absorption structure 108 is within a range of +10% and −10% of a first concentration value, within a range of +5% and −5% of the first concentration value, within a range of +2% and −2% of the first concentration value, where the first concentration value is equal to or greater than 1×10¹⁹ atoms/cm³ or is within a range of approximately 2×10¹⁸ to 5×10²⁰ atoms/cm³. In yet further embodiments, the doping concentration of the absorption structure 108 may vary across a width or height of the absorption structure 108. In such embodiments, at least the majority of the volume (e.g., at least 50% of the volume) of the absorption structure 108 is heavily doped (e.g., greater than approximately 2×10¹⁸ atoms/cm³).

In some embodiments, regions of the substrate 102 around the absorption structure 108 comprise the first doping type (e.g., p-type) and are lightly doped. A doping concentration of the substrate 102 is less than the first doping concentration of the absorption structure 108. A doping concentration of the first contact region 128 may, for example, be within a range of approximately 1×10¹⁸ to 1×10²⁰ atoms/cm³ or some other suitable value. In some embodiments, the doping concentration of the absorption structure 108 is greater than the doping concentration of the first contact region 128. In further embodiments, the doping concentration of the absorption structure 108 is less than the doping concentration of the first contact region 128. The doping concentration of the vertical connection region 126 may, for example, be within a range of approximately 1×10¹⁷ to 1×10²⁰ atoms/cm³ or some other suitable value. The doping concentration of the lateral connection region 124 and/or the first avalanche well 112 may, for example, be within a range of approximately 1×10¹⁷ to 1×10²⁰ atoms/cm³ or some other suitable value. The doping concentration of the second avalanche well 116 may, for example, be within a range of approximately 1×10¹⁷ to 1×10²⁰ atoms/cm³ or some other suitable value. In some embodiments, the doping concentration of the absorption structure 108 is greater than the doping concentrations of the first avalanche well 112, the second avalanche well 116, the vertical connection region 126, and/or the lateral connection region 124.

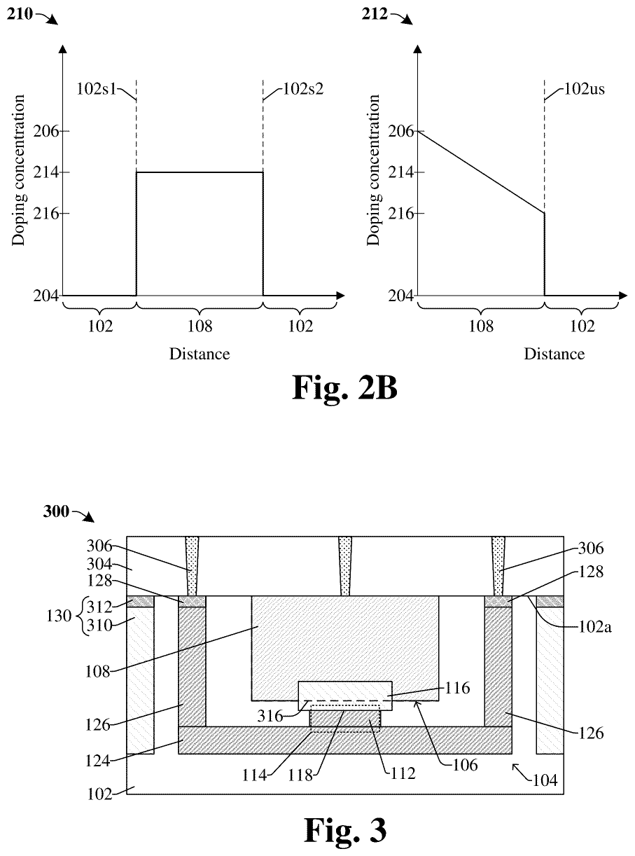

FIGS. 2A and 2B illustrate some embodiments of graphs showing doping profiles for various embodiments of the absorption structure 108.

FIG. 2A illustrates some embodiments of a first graph 202 taken along a width of the absorption structure 108 and a second graph 208 taken along a thickness of the absorption structure 108. In some embodiments, the first graph 202 is taken along line 136 of FIG. 1 and the second graph 208 is taken along line 138 of FIG. 1.

As illustrated in the first graph 202, the doping concentration of the substrate 102 remains substantially constant at a first value 204 outside of the inner sidewalls 102s1, 102s2 of the substrate 102. In some embodiments, the doping concentration of the substrate 102 increases rapidly over a short distance (e.g., within a range of approximately 5 to 50 angstroms or some other suitable) along edges of the absorption structure 108 to a second value 206 that is greater than the first value 204.

As illustrated in the second graph 208, the doping concentration of the substrate 102 remains substantially constant at the first value 204 below the upper surface 102us of the substrate 102. In some embodiments, the doping concentration of the substrate 102 increases rapidly over a short distance (e.g., within a range of approximately 5 to 50 angstroms or some other suitable value) along a lower surface of the absorption structure 108 to a second value 206. As seen in both the first graph 202 and the second graph 208, the doping concentration of the absorption structure 108 is substantially constant or uniform across the width and thickness of the absorption structure 108. The absorption structure 108 having the substantially constant doping concentration increases an ability for the absorption structure 108 to decrease dark current and provides better control during fabrication. In various embodiments, the first value 204 may be equal to or less than approximately 1×10¹⁵ atoms/cm³, equal to or less than approximately 1×10¹⁶ atoms/cm³, equal to or less than approximately 5×10¹⁶ atoms/cm³, or some other suitable value. In some embodiments, the second value 206 is greater than approximately 2×10¹⁸ atoms/cm³, equal to or greater than approximately 1×10¹⁹ atoms/cm³, within a range of approximately 2×10¹⁸ to 5×10²⁰ atoms/cm³, or some other suitable value. In various embodiments, substantially constant corresponds to being within a range of +10% and −10% of a specified value, within a range of +5% and −5% of a specified value, or within a range of +2% and −2% of a specified value.

FIG. 2B illustrates some embodiments of a third graph 210 taken along the width of the absorption structure and a fourth graph 212 taken along the thickness of the absorption structure 108. In some embodiments, the third graph 210 is taken along line 136 of FIG. 1 and the fourth graph 212 is taken along line 138 of FIG. 1.

As illustrated in the third graph 210, the doping concentration of the substrate 102 remains substantially constant at the first value 204 and the doping concentration of the absorption structure 108 across the width of the absorption structure 108 remains substantially constant at a third value 214 less than the second value 206.

As illustrated in the fourth graph 212, the doping concentration of the absorption structure 108 across the thickness of the absorption structure 108 gradually decreases from the second value 206 (e.g., at a top surface of the absorption structure) to a fourth value 216. The fourth value 216 is less than the third value 214. In various embodiments, the third value 214 is at a midpoint between the second value 206 and the fourth value 216. Thus, in some embodiments, the doping concentration across the thickness of the absorption structure 108 has a gradient profile and the doping concentration across the width of the absorption structure is substantially constant. In various embodiments, the second value 206 is equal to or greater than approximately 1×10¹⁹ atoms/cm³, within a range of approximately 1×10¹⁹ to 5×10²⁰ atoms/cm³, or some other suitable value. In various embodiments, the fourth value 216 is greater than approximately 1×10¹⁷ or some other suitable value. In some embodiments, the third value 214 is equal to or greater than approximately 2×10¹⁸ atoms/cm³ or some other suitable value. In yet further embodiments, the doping concentration across the thickness of the absorption structure 108 gradually increases from a bottom surface of the absorption structure 108 (e.g., increases from the second value 206) to the top surface of the absorption structure 108 (e.g., where the doping concentration at the top surface of the absorption structure 108 is at the fourth value 216).

FIG. 3 illustrates a cross-sectional view 300 of some embodiments of an image sensor including a photodetector that comprises an absorption structure with a relatively high doping concentration. The image sensor of FIG. 3 may correspond to some other embodiments of the image sensor of FIG. 1.

The image sensor includes a substrate 102 that comprises a recess 106 extending into a first surface 102a of the substrate 102. The substrate 102 comprises a first material (e.g., silicon). A photodetector 104 comprises an absorption structure 108 arranged in the recess 106 and an avalanche region 114 in the substrate 102. The absorption structure 108 comprises a second material (e.g., germanium) different from the first material (e.g., silicon). The absorption structure 108 is heavily doped with the first doping type (e.g., p-type). A first avalanche well 112 is arranged in the substrate 102 below the absorption structure 108. A second avalanche well 116 is arranged between the first avalanche well 112 and the absorption structure 108.

A lateral connection region 124 is arranged in the substrate 102 below the absorption structure 108. A first contact region 128 is arranged in the substrate 102 along the first surface 102a. In some embodiments, the first contact region 128 continuously laterally extends around the absorption structure 108 when viewed from above and is ring shaped. In yet further embodiments, the first contact region 128 comprises two or more discrete regions arranged on opposing sides of the absorption structure 108. A vertical connection region 126 is arranged on opposing sides of the lateral connection region 124 and continuously extends from the first contact region 128 to the lateral connection region 124. In various embodiments, the vertical connection region 126 continuously laterally extends around the absorption structure 108 when viewed from above and is ring shaped. In yet further embodiments, the vertical connection region 126 comprises two or more discrete regions arranged on opposing sides of the absorption structure 108.

In some embodiments, the first avalanche well 112 overlies a middle region of the lateral connection region 124. The second avalanche well 116 comprises the first doping type (e.g., p-type) and the first avalanche well 112 comprises the second doping type (e.g., n-type) opposite the first doping type. The first avalanche well 112 contacts the second avalanche well 116 at a PN junction 118 above the lateral connection region 124. A doping concentration of the first avalanche well 112 may, for example, be within a range of approximately 1×10¹⁷ to 1×10²⁰ atoms/cm³ or some other suitable value. In some embodiments, a width of the first avalanche well 112 is less than a width of the second avalanche well 116.

The second avalanche well 116 continuously extends from the substrate 102 into a bottom surface 316 of the absorption structure 108. In some embodiments, by virtue of the second avalanche well 116 continuously extending from a lower region of the absorption structure 108 into the substrate 102, the avalanche breakdown voltage of the photodetector 104 is decreased (e.g., an absolute value of the breakdown voltage is decreased). As a result, a power consumption and/or noise of the photodetector 104 may be decreased. In various embodiments, the second avalanche well 116 comprises the first doping type (e.g., p-type) and has a doping concentration less than that of the bulk of the absorption structure 108. The bulk of the absorption structure 108 corresponds to a portion of the absorption structure 108 that is over and around the second avalanche well 116. In some embodiments, a segment of the second avalanche well 116 arranged in the absorption structure 108 occupies approximately 1% to 6% of a total volume of the absorption structure 108. The segment of the second avalanche well 116 occupying 1% to 6% of a total volume of the absorption structure 108 facilitates reducing the avalanche breakdown voltage of the photodetector 104 while maintaining the high doping concentration across the absorption structure 108 to decrease dark current.

The isolation structure 130 comprises a first isolation region 310 in the substrate 102 and a second isolation region 312 in the substrate 102 and over the first isolation region 310. In some embodiments, the isolation structure 130 continuously laterally extends around the vertical connection region 126 and the lateral connection region 124 when viewed in top view and is ring shaped. The isolation structure 130 is configured to increase electrical isolation between the photodetector 104 and other photodetectors (not shown) or other devices (not shown) arranged in and/or on the substrate 102. In some embodiments, the first isolation region 310 and the second isolation region 312 comprise the first doping type (e.g., p-type), where a doping concentration of the second isolation region 312 is greater than a doping concentration of the second isolation region 312. In various embodiments, the doping concentrations of the first and second isolation regions 310, 312 are each less than the doping concentration of the absorption structure 108.

A dielectric structure 304 is arranged on the first surface 102a of the substrate 102. The dielectric structure 304 comprises one or more dielectric layers. The one or more dielectric layers may, for example, be or comprise an oxide (e.g., silicon dioxide), a nitride (e.g., silicon nitride, silicon carbide, etc.), some other suitable dielectric, or any combination of the foregoing. A plurality of conductive contacts 306 are arranged in the dielectric structure 304 and are configured to facilitate electrical coupling to the photodetector 104. The plurality of conductive contacts 306 may, for example, be or comprise tungsten, titanium nitride, tantalum nitride, aluminum, copper, some other conductive material, or any combination of the foregoing.

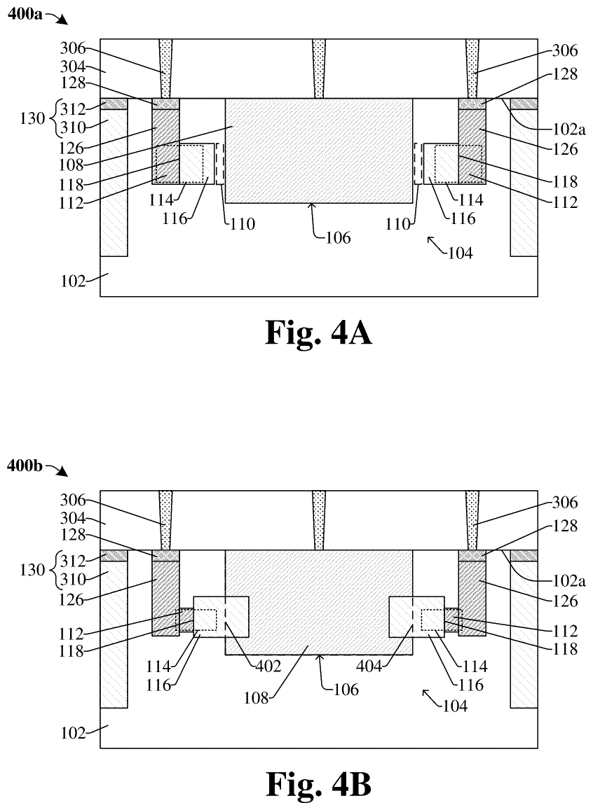

FIG. 4A illustrates a cross-sectional view 400a of some other embodiments of the image sensor of FIG. 1, in which the first and second avalanche wells 112, 116 are arranged on opposing sides of the absorption structure 108. In various embodiments, the first avalanche well 112 is part of the vertical connection region 126 and the lateral connection region (124 of FIG. 1) is omitted. For example, the first avalanche well 112 may be arranged in a lower portion of the vertical connection region 126.

In some embodiments, the first avalanche well 112 is arranged on opposing sides of the absorption structure 108 and is above a bottom surface of the absorption structure 108. In various embodiments, the second avalanche well 116 is arranged laterally between opposing sidewalls of the absorption structure 108 and the first avalanche well 112. Accordingly, the avalanche region 114 is arranged laterally between the opposing sidewalls of the absorption structure 108 and the first avalanche well 112. In some embodiments, the first avalanche well 112 continuously laterally extends around the absorption structure 108 when viewed in top view and is ring shaped. In such embodiments, the second avalanche well 116 and the region 110 are each ring shaped when viewed in top view. In yet further embodiments, the first avalanche well 112 and the second avalanche well 116 respectively comprises two segments arranged on opposing sides of the absorption structure 108. Thus, the PN junction 118 may be spaced laterally from the absorption structure 108. In some embodiments, during operation of the image sensor, a released charge carrier (e.g., released electron) from absorbed target incident radiation may travel laterally from the absorption structure 108 to the avalanche region 114 on either side of the absorption structure 108.

FIG. 4B illustrates a cross-sectional view 400b of some other embodiments of the image sensor of FIG. 4A, in which the second avalanche well 116 extends laterally into opposing sidewalls 402, 404 of the absorption structure 108.

In some embodiments, the second avalanche well 116 continuously extends laterally from the substrate 102 into the opposing sidewalls 402, 404 of the absorption structure 108. By virtue of the second avalanche well 116 being disposed at least partially in the absorption structure 108, the avalanche breakdown voltage of the photodetector 104 is decreased (e.g., an absolute value of the breakdown voltage is decreased). As a result, a power consumption and/or noise of the photodetector 104 may be decreased. In some embodiments, one or more segments of the second avalanche well 116 arranged in the absorption structure 108 occupies approximately 1% to 6% of a total volume of the absorption structure 108. Further the first avalanche well 112 continuously extends from the second avalanche well 116 to one or more sides of the vertical connection region 126. In various embodiments, a height of the first avalanche well 112 is less than a height of the second avalanche well 116.

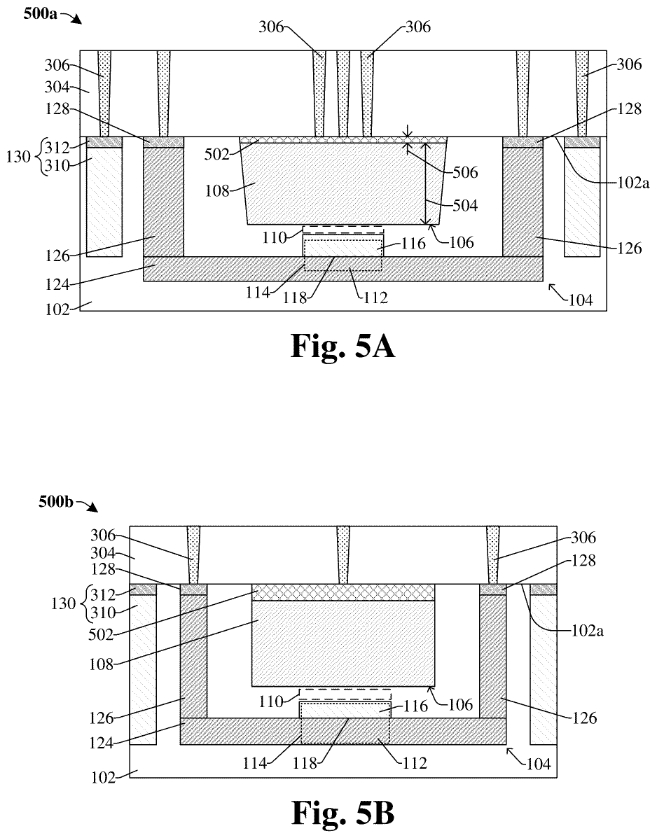

FIG. 5A illustrates a cross-sectional view 500a of some other embodiments of the image senor of FIG. 1, in which a capping layer 502 is disposed on the absorption structure 108.

The dielectric structure 304 overlies the substrate 102. The plurality of conductive contacts 306 are arranged in the dielectric structure 304. In some embodiments, an upper surface of the absorption structure 108 is recessed below the first surface 102a of the substrate. The capping layer 502 continuously extends along and contacts the upper surface of the absorption structure 108. In some embodiments, outer sidewalls of the capping layer 502 are aligned with outer sidewalls of the absorption structure 108. In various embodiments, the outer sidewalls of the capping layer 502 contact inner sidewalls of the substrate 102 that define the recess 106. The outer sidewalls of the capping layer 502 and the outer sidewalls of the absorption structure 108 may be slanted.

The capping layer 502 comprises the first doping type (e.g., p-type) with a high doping concentration. In some embodiments, the doping concentration of the capping layer 502 is greater than the doping concentration of the absorption structure 108. The doping concentration of the capping layer 502 may, for example, be greater than approximately 1×10¹⁹ atoms/cm³, within a range of approximately 5×10¹⁸ to 1×10²¹ atoms/cm³, or some other suitable value. In various embodiments, the high doping concentration of the capping layer 502 further decreases dark current in the photodetector 104 and provides for a lower contact resistance for the overlying conductive contacts. In various embodiments, at least three conductive contacts 306 overlie and contact the capping layer 502 to provide for a good electrical connection with the capping layer 502. A thickness 504 of the absorption structure 108 may, for example, be greater than approximately 1 micrometer (um), within a range of approximately 1 to 2 um, or some other suitable value. A thickness 506 of the capping layer 502 may, for example, be greater than approximately 30 nm, within a range of approximately 30 to 60 nm, or some other suitable value. In some embodiments, the thickness 504 of the absorption structure 108 is greater than the thickness 506 of the capping layer 502.

The substrate 102 comprises the first material (e.g., silicon) and the absorption structure 108 comprises the second material (e.g., germanium) different from the first material. The capping layer 502 may be configured to mitigate damage to the absorption structure 108 during fabrication of the image sensor. For example, the capping layer 502 may decrease damage to the absorption structure 108 during one or more wet etch processes performed on the substrate 102 after forming the capping layer 502 over the absorption structure 108. In some embodiments, the capping layer 502 comprises the second material (e.g., germanium). In such embodiments, the capping layer 502 comprising a same material as the absorption structure 108 decreases defects at interfaces between the capping layer 502 and the absorption structure 108, thereby further decreasing dark current. In yet further embodiments, the capping layer 502 comprises the first material (e.g., silicon), silicon germanium, or some other suitable material.

FIG. 5B illustrates a cross-sectional view 500b of some other embodiments of the image sensor of FIG. 5A, in which the outer sidewalls of the capping layer 502 and the outer sidewalls of the absorption structure 108 are substantially straight.

FIG. 5C illustrates a cross-sectional view 500c of some other embodiments of the image sensor of FIG. 4A, in which a capping layer 502 is arranged on the upper surface of absorption structure 108. In some embodiments, the capping layer 502 may be configured as illustrated and/or described in FIG. 5A or 5B.

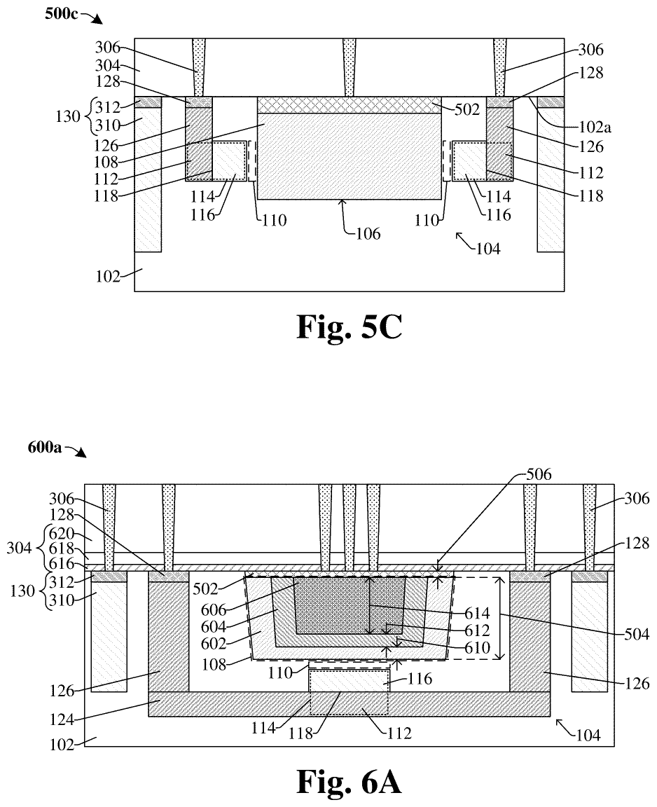

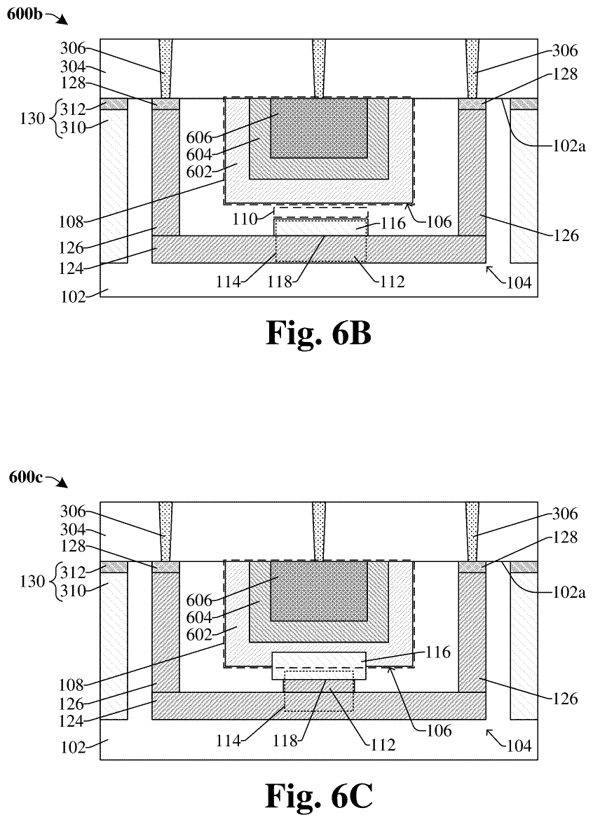

FIG. 6A illustrates a cross-sectional view 600a of some other embodiments of the image sensor of FIG. 5A, in which the absorption structure 108 includes a plurality of doped layers 602-606.

The plurality of doped layers 602-606 includes a first doped layer 602, a second doped layer 604, and a third doped layer 606. In some embodiments, each layer in the plurality of doped layers 602-606 is an individual doped epitaxial layer comprising the second material (e.g., germanium). In further embodiments, the plurality of doped layers 602-606 may each be an individual doped region (e.g., formed by a selective ion implantation process) of the absorption structure 108. The first doped layer 602 has a first doping concentration of the first doping type (e.g., p-type), the second doped layer 604 has a second doping concentration of the first doping type, and the third doped layer 606 has a third doping concentration of the first doping type. The plurality of doped layers 602-606 respectively comprise one or more first dopants (e.g., boron, gallium, etc.). In some embodiments, the plurality of doped layers 602-606 each comprise a same dopant (e.g., boron or gallium). In yet further embodiments, two or more of the plurality of doped layers 602-606 comprise different dopants from one another that each have the first doping type (e.g., p-type). For example, the first doped layer 602 may comprise boron and the second doped layer 604 may comprise gallium.

In various embodiments, the first doping concentration, the second doping concentration, and the third doping concentration are different from one another and are each greater than approximately 1×10¹⁶ atoms/cm³. In further embodiments, at least one of the first, second, and third doping concentrations of the plurality of doped layers 602-606 is greater than 2×10¹⁸ atoms/cm³ and/or greater than doping concentrations of the first avalanche well 112, the second avalanche well 116, and/or the vertical connection region 126. In yet further embodiments, the first, second, and third doping concentrations of the plurality of doped layers 602-606 are configured such that at least a majority of the volume (e.g., at least 50% of the volume) of the absorption structure 108 is highly doped (e.g., doping concentration greater than approximately 2×10¹⁸ atoms/cm³).

In some embodiments, the first doping concentration of the first doped layer 602 is less than the second doping concentration of the second doped layer 604, and the third doping concentration of the third doped layer 606 is greater than the second doping concentration of the second doped layer 604. In various embodiments, the change of doping concentrations across the plurality of doped layers 602-606 may decrease dark current in the photodetector 104 and enhance an electric field across the absorption structure 108, thereby increasing an overall performance of the photodetector 104. In an embodiment, the first doping concentration of the first doped layer 602 may be approximately 3×10¹⁸ atoms/cm³, the second doping concentration of the second doped layer 604 may be approximately 5×10¹⁸ atoms/cm³, and the third doping concentration of the third doped layer 606 may be approximately 2×10¹⁹ atoms/cm³. In another embodiment, the first doping concentration of the first doped layer 602 may be approximately 1×10¹⁸ atoms/cm³, the second doping concentration of the second doped layer 604 may be approximately 5×10¹⁸ atoms/cm³, and the third doping concentration of the third doped layer 606 may be approximately 1×10¹⁹ atoms/cm³. In yet another embodiment, the first doping concentration of the first doped layer 602 may be approximately 5×10¹⁶ atoms/cm³, the second doping concentration of the second doped layer 604 may be approximately 1×10¹⁸ atoms/cm³, and the third doping concentration of the third doped layer 606 may be approximately 1×10¹⁹ atoms/cm³. In various embodiments, the first doping concentration of the first doped layer 602 is greater than the second doping concentration of the second doped layer 604, and the third doping concentration of the third doped layer 606 is less than the second doping concentration of the second doped layer 604.

In yet further embodiments, a maximum doping concentration of an individual layer in the plurality of doped layers 602-606 is at least ten times greater than a minimum doping concentration of another individual layer in the plurality of doped layers 602-606. For example, the third doping concentration of the third doped layer 606 is at least ten times greater than the first doping concentration of the first doped layer 602. In various embodiments, the doping concentration of the capping layer 502 is greater than the first, second, and third doping concentrations of the plurality of doped layers 602-606.

The plurality of doped layers 602-606 have corresponding thicknesses 610-614. The first doped layer 602 has a first thickness 610, the second doped layer 604 has a second thickness 612, and the third doped layer 606 has a third thickness 614. In some embodiments, the third thickness 614 is greater than the first thickness 610 and the second thickness 612. In further embodiments, the first thickness 610 is less than the second thickness 612 and the third thickness 614. Further, the thicknesses 610-614 of the plurality of doped layers 602-606 are each greater than the thickness 506 of the capping layer 502. In various embodiments, the first, second, and third doping concentrations are substantially constant across respective thicknesses 610-614 of the plurality of doped layers 602-606. In further embodiments, the first, second, and/or third doping concentrations gradually increase across respective thicknesses 610-614 of the plurality of doped layers 602-606. In further embodiments, the first, second, and third doping concentrations of the plurality of doped layers 602-606 respectively gradually increase from a bottom surface of the absorption structure 108 in a first direction towards the capping layer 502. In yet further embodiments, the first, second, and third doping concentrations of the plurality of doped layers 602-606 respectively gradually decrease from the bottom surface of the absorption structure 108 in the first direction towards the capping layer 502. In various embodiments, the plurality of doped layers 602-606 respectively comprise or occupy approximately 25 to 40 percent of a total volume of the absorption structure 108, where the doped layers 602-606 collectively occupy the total volume of the absorption structure 108. In some embodiments, the first doped layer 602 occupies a first volume of the absorption structure 108 and the second doped layer 604 occupies a second volume of the absorption structure 108 that is less than the first volume.

In some embodiments, a top surface of the first doped layer 602, a top surface of the second doped layer 604, and a top surface of the third doped layer 606 are respectively aligned with one another. Further, as viewed in cross-section the first doped layer 602 and the second doped layer 604 are each U-shaped. The first doped layer 602 extends along opposing sidewalls and a bottom surface of the second doped layer 604 and the second doped layer 604 continuously extends along opposing sidewalls and a bottom surface of the third doped layer 606.

Further, the dielectric structure 304 comprises a contact etch stop layer (CESL) 616, a first dielectric layer 618 on the CESL 616, and a second dielectric layer 620 over the first dielectric layer 618. The CESL 616 may, for example, be or comprise silicon nitride, silicon carbide, silicon oxynitride, or the like. The first dielectric layer 618 and the second dielectric layer 620 may, for example, each be or comprise an oxide (e.g., silicon dioxide), a low-k dielectric material (e.g., a dielectric material having a dielectric constant less than 3.9), or the like.

FIG. 6B illustrates a cross-sectional view 600b of some other embodiments of the image sensor of FIG. 6A, in which the capping layer (502 of FIG. 6A) is omitted. In some embodiments, top surfaces of the first doped layer 602, the second doped layer 604, and the third doped layer 606 are respectively aligned with the first surface 102a of the substrate 102.

FIG. 6C illustrates a cross-sectional view 600c of some other embodiments of the image sensor of FIG. 6B, in which the second avalanche well 116 continuously extends from the substrate 102 into the absorption structure 108.

As seen in FIG. 6C, the second avalanche well 116 extends from the substrate 102 into the first doped layer 602. In some embodiments, a doping concentration of the second avalanche well 116 is less than that of the first doped layer 602. In yet further embodiments, the doping concentration of the second avalanche well 116 is greater than that of the first doped layer 602 and less than that of the second and/or third doped layers 604, 606. Further, a segment of the second avalanche well 116 arranged in the absorption structure 108 occupies, for example, approximately 1% to 6% of a total value of the absorption structure 108 or some other suitable value.

FIG. 6D illustrates a cross-sectional view 600d of some other embodiments of the image sensor of FIG. 6A, in which outer sidewalls of the capping layer 502 and outer sidewalls of the absorption structure 108 are aligned and substantially straight.

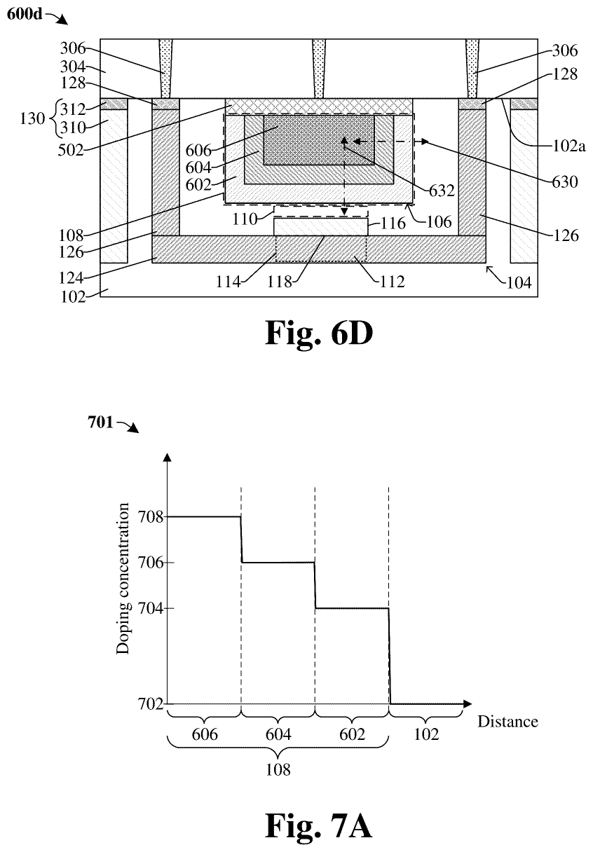

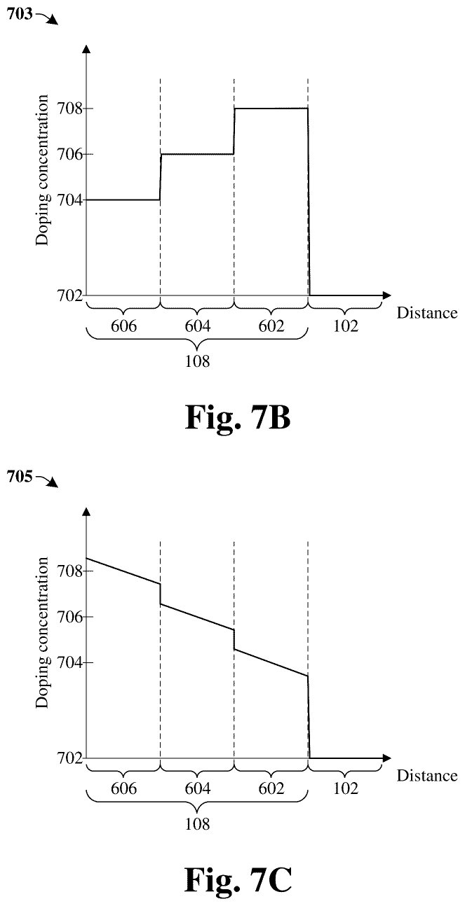

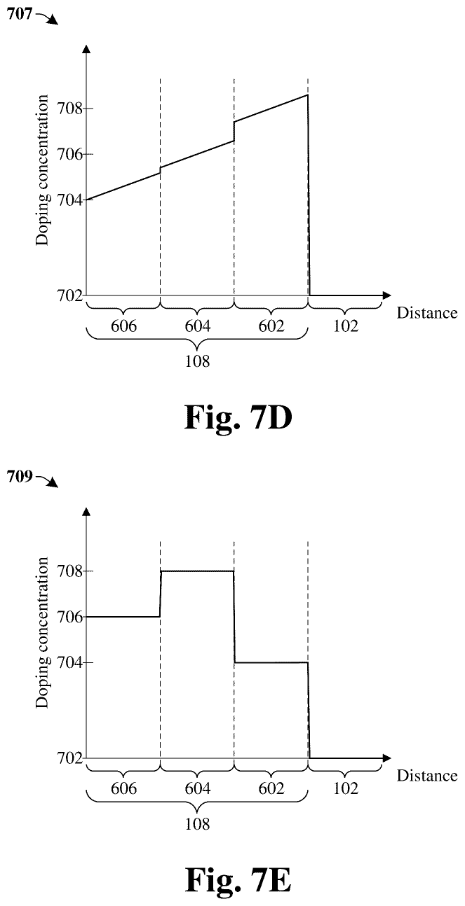

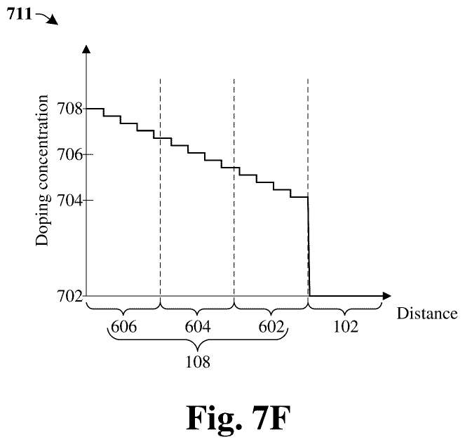

FIGS. 7A-7F illustrate some embodiments of graphs showing doping profiles for various embodiments of the absorption structure 108. The graphs of FIGS. 7A-7F may correspond to doping profiles of the plurality of doped layers 602-606 of the absorption structure 108. In some embodiments, the FIGS. 7A-7F correspond to the doping profiles of the absorption structure 108 taken along line 630 and/or line 632 of FIG. 6D. It will be appreciated that while the doping profiles are provided in regards to the image sensor of FIG. 6D, these doping profiles may correspond to any one of FIGS. 6A, 6B, 6C, 8A, 8B, 9B, and 10E-10H.

As illustrated in graph 701 of FIG. 7A, in some embodiments the doping concentration of the substrate 102 remains substantially constant at a first value 702, the doping concentration of the first doped layer 602 remains substantially constant at a second value 704, the doping concentration of the second doped layer 604 remains substantially constant at a third value 706, and the doping concentration of the third doped layer 606 remains substantially constant at a fourth value 708. In various embodiments, the graph 701 is taken along both the line 630 and the line 632 of FIG. 6D. The first value 702 is less than the second value 704, the third value 706 is greater than the second value 704, and the fourth value 708 is greater than the third value 706. Thus, in some embodiments, the doping concentration of the absorption structure 108 discretely decreases at least two times across a thickness and/or a width of the absorption structure 108.

As illustrated in graph 703 of FIG. 7B, in some embodiments the doping concentration of the first doped layer 602 is substantially constant at the fourth value 708, the doping concentration of the second doped layer 604 is substantially constant at the third value 706, and the doping concentration of the third doped layer 606 is substantially constant at the second value 704. In various embodiments, the graph 703 is taken along both the line 630 and the line 632 of FIG. 6D.

As illustrated in graph 705 of FIG. 7C, in some embodiments the doping concentrations across the first doped layer 602, the second doped layer 604, and the third doped layer 606 respectively continuously decrease in a first direction from a top surface of the absorption structure 108 towards the substrate 102. In some embodiments, the graph 705 is taken along the line 632 of FIG. 6D. The first doped layer 602, the second doped layer 604, and the third doped layer 606 may each have a gradient doping profile.

As illustrated in graph 707 of FIG. 7D, in some embodiments the doping concentrations across the first doped layer 602, the second doped layer 604, and the third doped layer 606 respectively continuously increase in a first direction from a top surface of the absorption structure 108 towards the substrate 102. In some embodiments, the graph 707 is taken along the line 632 of FIG. 6D.

As illustrated in graph 709 of FIG. 7E, in some embodiments the doping concentration of the second doped layer 604 is greater than the doping concentration of the third doped layer 606, and the doping concentration of the first doped layer 602 is less than the doping concentration of the third doped layer 606. In various embodiments, the doping concentrations of the first, second, and third doped layers 602, 604, 606 are respectively substantially constant. In various embodiments, the graph 709 is taken along both the line 630 and the line 632 of FIG. 6D.

As illustrated in graph 711 of FIG. 7F, in some embodiments the doping concentrations of the first, second, and third doped layers 602, 604, 606 each have a stepped profile that discretely decreases multiple times in a first direction from a top surface of the absorption structure 108 towards the substrate 102. In some embodiments, the graph 711 is taken along the line 632 of FIG. 6D.

In regards to the graphs of FIGS. 7A-7F, in some embodiments, the first value 702 is equal to or less than approximately 1×10¹⁵ atoms/cm³, equal to or less than approximately 1×10¹⁶ atoms/cm³, equal to or less than approximately 5×10¹⁶ atoms/cm³, or some other suitable value. In various embodiments, one or more of the third value 706 and the fourth value 708 is greater than approximately 2×10¹⁸ atoms/cm³. In further embodiments, the second value 704 is greater than approximately 2×10¹⁸ atoms/cm³. In yet further embodiments, the second value 704 is less than approximately 2×10¹⁸ atoms/cm³. In some embodiments, the fourth value 708 is greater than approximately 2×10¹⁸ atoms/cm³, equal to or greater than approximately 1×10¹⁹ atoms/cm³, within a range of approximately 2×10¹⁸ to 5×10²⁰ atoms/cm³, or some other suitable value.

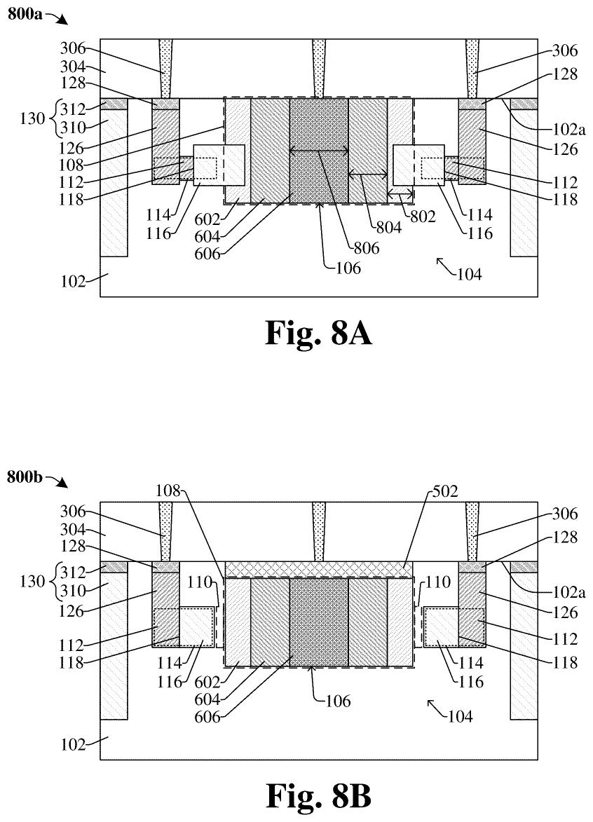

FIG. 8A illustrates a cross-sectional view 800a of some other embodiments of the image sensor of FIG. 4B, in which the absorption structure 108 includes a plurality of doped layers 602-606.

In various embodiments, the plurality of doped layers 602-606 may be configured as illustrated and/or described in FIG. 6A. In some embodiments, the plurality of doped layers 602-606 may have equal heights or thicknesses. Further, the plurality of doped layers 602-606 have corresponding widths 802-804. The first doped layer 602 has a first width 802, the second doped layer 604 has a second width 804, and the third doped layer 606 has a third width 806. In some embodiments, the first width 802 is less than the second width 804, and the third width 806 is greater than the second width 804. The second doped layer 604 is arranged on opposing sides of the first doped layer 602 and continuously laterally wraps around the third doped layer 606. The first doped layer 602 is arranged on opposing sides of the second doped layer 604 and continuously laterally wraps around the second doped layer 604. In some embodiments, when viewed in top view the first doped layer 602 and the second doped layer 604 layer are each ring shaped.

In some embodiments, each layer in the plurality of doped layers 602-606 is an individual doped epitaxial layer comprising the second material (e.g., germanium). In further embodiments, the plurality of doped layers 602-606 may each be an individual doped region (e.g., formed by a selective ion implantation process) of the absorption structure 108. In some embodiments, the first doping concentration of the first doped layer 602 is less than the second doping concentration of the second doped layer 604, and the third doping concentration of the third doped layer 606 is greater than the second doping concentration of the second doped layer 604. In various embodiments, doping concentrations of the doped layers 602-606 respectively increase or decrease from a top surface of a corresponding doped layer in a first direction towards a bottom surface of the substrate 102. In further embodiments, doping concentrations of the doped layers 602-606 respectively have a stepped profile that discretely decreases multiple times in the first direction.

FIG. 8B illustrates a cross-sectional view 800b of some other embodiments of the image sensor of FIG. 8A, in which the second avalanche well 116 is laterally offset from the absorption structure 108 and a capping layer 502 extends along a top surface of the absorption structure 108. The capping layer 502 directly contacts top surfaces of the plurality of doped layers 602-606.

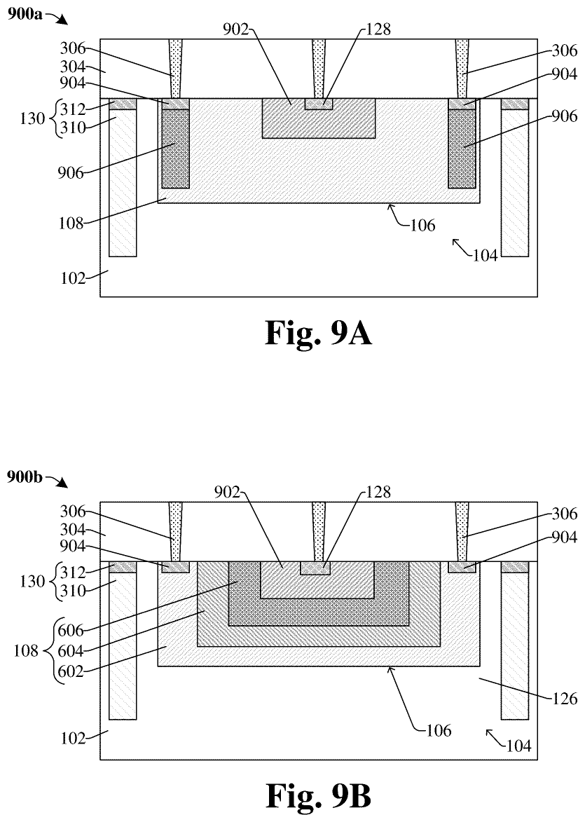

FIG. 9A illustrates a cross-sectional view 900a of some embodiments of an image sensor include a photodetector that comprises an absorption structure with a relatively high doping concentration.

The image sensor comprises a substrate 102. The substrate 102 comprises a first material (e.g., silicon). The substrate 102 may, for example, be lightly doped with a first doping type (e.g., p-type). A photodetector 104 is arranged in the substrate 102 and comprises an absorption structure 108 arranged in a recess 106 of the substrate 102 and a first well region 902 and a second well region 906. The absorption structure 108 comprises a second material (e.g., germanium) having a smaller bandgap than the first material. Further, a bulk of the absorption structure 108 is heavily doped with the first doping type (e.g., p-type). In some embodiments, a doping concentration of the bulk of the absorption structure 108 is, for example, greater than approximately 2×10¹⁸ atoms/cm³, equal to or greater than approximately 1×10¹⁹ atoms/cm³, within a range of approximately 2×10¹⁸ to 5×10²⁰ atoms/cm³, or some other suitable value. The bulk of the absorption structure 108 is a region of the absorption structure 108 around other doped regions in the absorption structure 108 (e.g., a region of the absorption structure 108 around the first well region 902 and the second well region 906). In various embodiments, the doping concentration of at least 50% of the bulk of the absorption structure 108 is greater than approximately 2×10¹⁸ atoms/cm³.

The first well region 902 comprises a second doping type (e.g., n-type) opposite the first doping type (e.g., p-type). Further, a first contact region 128 comprises the second doping type and is arranged in the first well region 902. A doping concentration of the first contact region 128 is greater than a doping concentration of the first well region 902. The doping concentration of the first well region 902 may, for example, be within a range of approximately 1×10¹⁷ to 1×10²⁰ atoms/cm³ or some other suitable value. In some embodiments, the doping concentration of the first well region 902 is less than the doping concentration of the bulk of the absorption structure 108. The second well region 906 comprises the first doping type (e.g., p-type) and is arranged on opposing ends of the absorption structure 108. A second contact region 904 comprises the first doping type and overlies the second well region 906. In some embodiments, the second well region 906 and the second contact region 904 are ring shaped when viewed in top view. In various embodiments, a doping concentration of the second well region 906 is greater than the doping concentration of the bulk of the absorption structure 108 and a doping concentration of the second contact region 904 is greater than the doping concentration of the second well region 906. The photodetector 104 may, for example, be a PN photodiode or some other suitable photodetector. In various embodiments, the bulk of the absorption structure 108 being heavily doped with the first doping type decreases dark current in the photodetector 104.

FIG. 9B illustrates a cross-sectional view 900b of some other embodiments of the image sensor of FIG. 9A, in which the absorption structure 108 comprises a plurality of doped layers 602-606 and the second well region (906 of FIG. 9A) is omitted. In various embodiments, the plurality of doped layers 602-606 may be configured as illustrated and/or described in FIG. 6A. Further, the second contact region 904 is arranged in the first doped layer 602 and has a doping concentration greater than that of the first doped layer 602. In various embodiments, the third doped layer 606 extends along opposing sides and a bottom of the first well region 902.

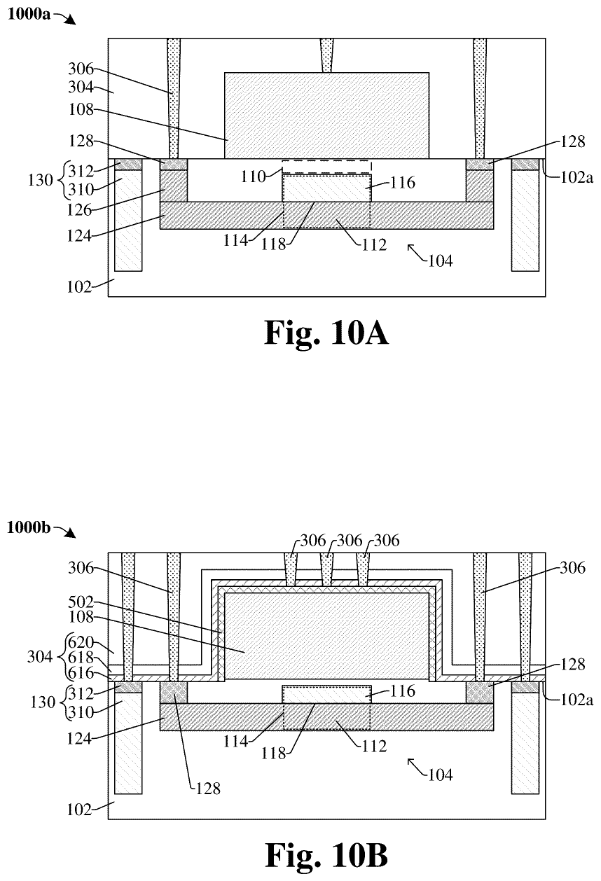

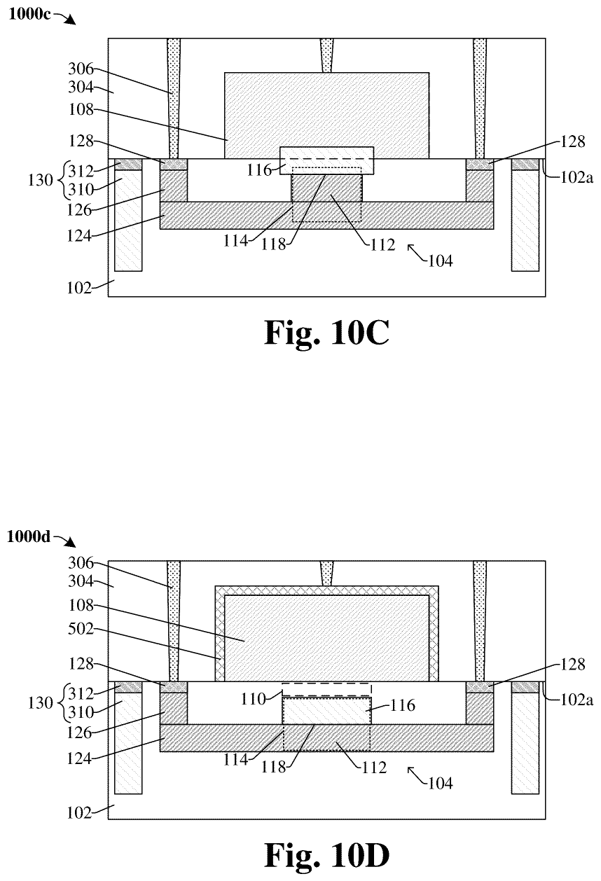

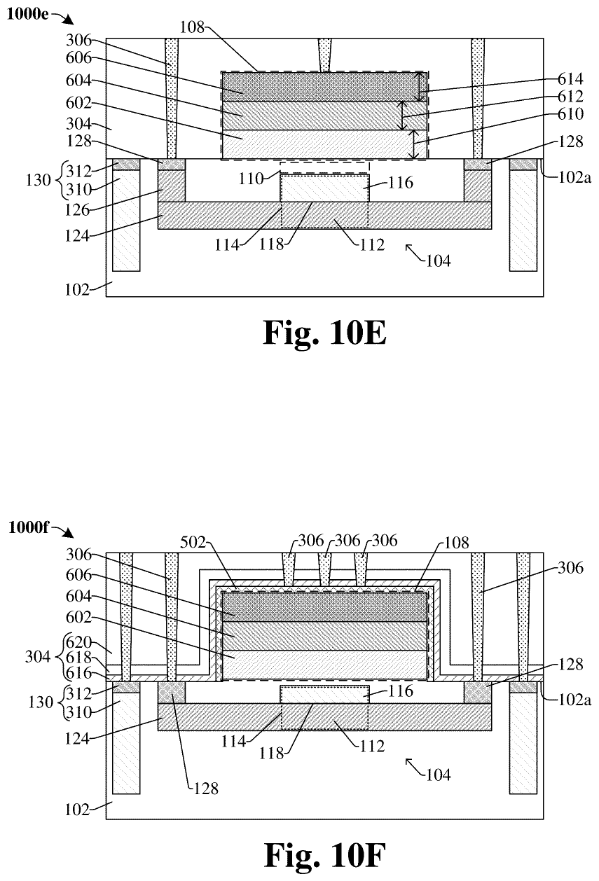

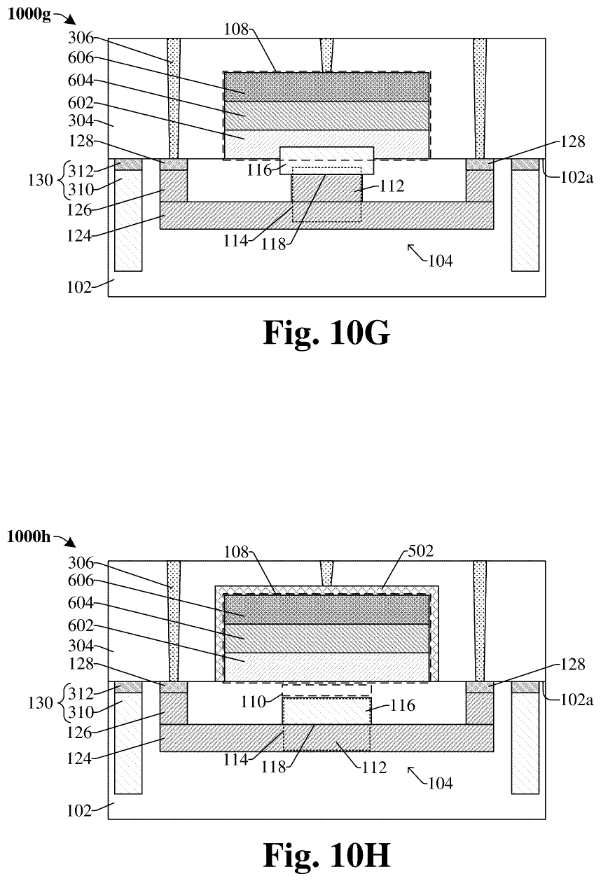

FIGS. 10A-10H illustrate cross-sectional views 1000a-1000h of various different embodiments of the image sensor of FIG. 1, in which the absorption structure 108 is arranged on and/or over the first surface 102a of the substrate 102.

With reference to the cross-sectional view 1000a of FIG. 10A, the absorption structure 108 contacts the first surface 102a of the substrate 102. The dielectric structure 304 laterally extends around opposing sidewalls of the absorption structure 108. In some embodiments, arranging the absorption structure 108 over the first surface 102a may decrease an area of interfaces between the substrate 102 and the absorption structure 108, thereby decreasing dark current. Further, arranging the absorption structure 108 over the first surface 102a increases isolation (e.g., electrical isolation) between the photodetector 104 and other photodetectors (not shown) arranged in and/or on the substrate 102.

With reference to the cross-sectional view 1000b of FIG. 10B, the capping layer 502 extends along a top surface and opposing sidewalls of the absorption structure 108. In some embodiments, a bottom surface of the capping layer 502 is arranged below a bottom surface of the absorption structure 108. In various embodiments, the doping concentration of the capping layer 502 along the top surface and the opposing sidewalls of the absorption structure 108 is greater than the doping concentration of the absorption structure 108. The CESL 616 overlies the first surface 102a of the substrate 102 and the capping layer 502. Further, the CESL 616 extends along opposing sidewalls of the capping layer 502.

With reference to the cross-sectional view 1000c of FIG. 10C, the second avalanche well 116 extends vertically from the first surface 102a of the substrate 102 into the absorption structure 108. As a result, the avalanche breakdown voltage of the photodetector 104 may be decreased.

With reference to the cross-sectional view 1000d of FIG. 10D, the capping layer 502 extends along a top surface and opposing sidewalls of the absorption structure 108. In some embodiments, a bottom surface of the capping layer 502 is aligned with the bottom surface of the absorption structure 108.

With reference to the cross-sectional view 1000e of FIG. 10E, the absorption structure 108 comprises a plurality of doped layers 602-606 that are each arranged above the first surface 102a of the substrate 102.

In some embodiments, FIG. 10E illustrates an alternative embodiment of the absorption structure of the photodetector 104 of FIG. 6A in which the plurality of doped layers 602-606 are each planar rather than one or more of the doped layers being U-shaped as in FIG. 6A. In various embodiments, outer sidewalls of the first doped layer 602, outer sidewalls of the second doped layer 604, and outer sidewalls of the third doped layer 606 are aligned with one another. Further, the doped layers 602-606 may have the doping profiles as illustrated and/or described in any one of FIGS. 7A-7C. In some embodiments, the thicknesses 610-614 of the plurality of doped layers 602-606 are equal to one another. In other embodiments, the thicknesses 610-614 are different from one another.

With reference to the cross-sectional view 1000f of FIG. 10F, the absorption structure 108 comprises a plurality of doped layers 602-606 that are each arranged above the first surface 102a of the substrate 102 and the capping layer 502 continuously extends along the opposing sidewalls of each layer in the plurality of doped layers 602-606.

With reference to the cross-sectional view 1000g of FIG. 10G, the absorption structure 108 comprises a plurality of doped layers 602-606 arranged above the first surface 102a of the substrate 102 and the second avalanche well 116 extends vertically from the first surface 102a of the substrate 102 into a first doped layer 602 of the plurality of doped layers 602-606.

With reference to the cross-sectional view 1000h of FIG. 10H, the absorption structure 108 comprises a plurality of doped layers 602-606 that are each arranged above the first surface 102a of the substrate 102 and the capping layer 502 continuously extends along the opposing sidewalls of each layer in the plurality of doped layers 602-606.

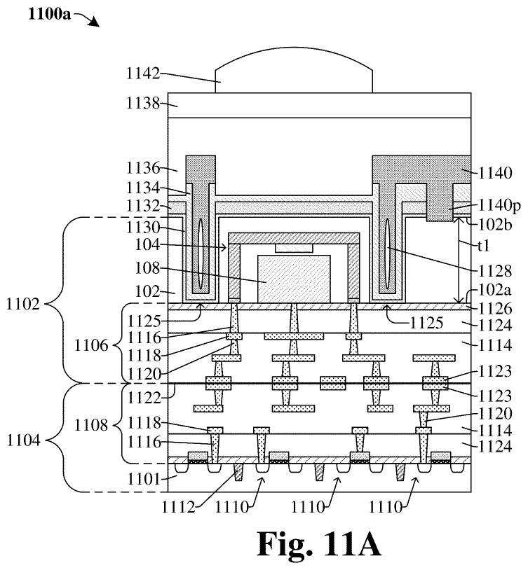

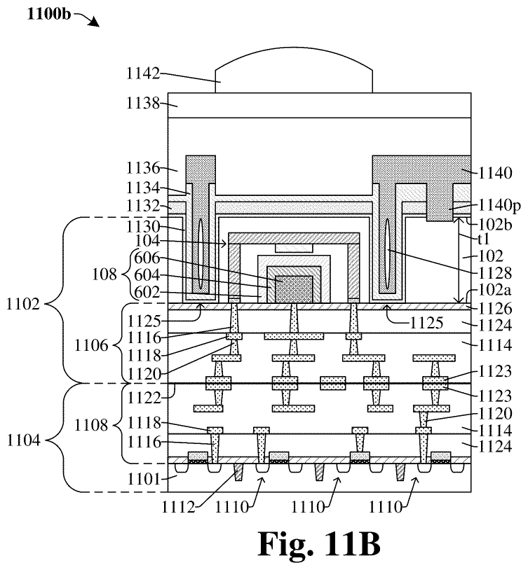

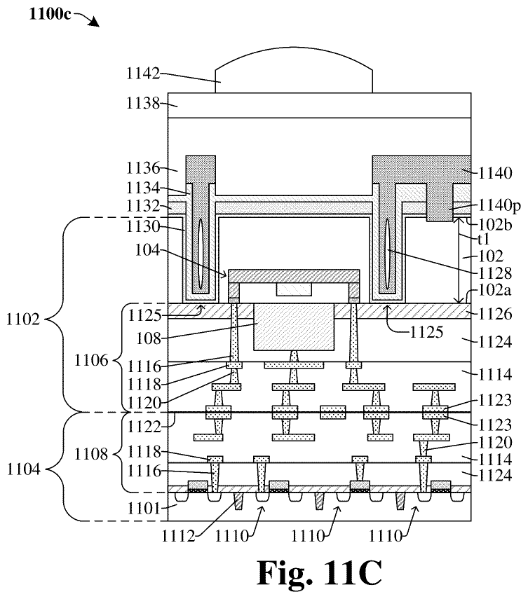

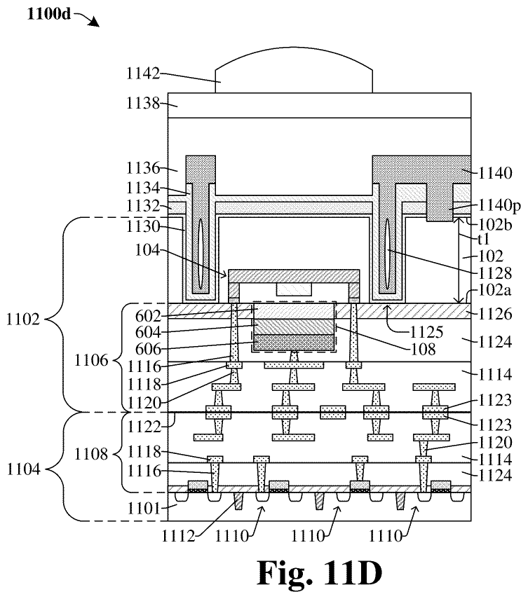

FIG. 11A illustrates a cross-sectional view 1100a of some embodiments of the image sensor of FIG. 1, in which the image sensor comprises a first integrated circuit (IC) chip 1102 and a second IC chip 1104.

In some embodiments, the photodetector 104 is arranged on the first IC chip 1102 and a plurality of logic devices 1110 are arranged on the second IC chip 1104. The photodetector 104 is disposed in a first substrate 102 of the first IC chip 1102. The photodetector 104 is configured as illustrated and/or described in FIG. 1, but may alternatively be as in any one or combination of FIGS. 3, 4A-4B, 5A-5C, 6A-6D, 8A-8B, 9A-9B, and 10A-10H.

The first IC chip 1102 comprises the first substrate 102 and a first interconnect structure 1106 arranged on a first surface 102a of the first substrate 102. The second IC chip 1104 comprises a second substrate 1101 and a second interconnect structure 1108 arranged on the second substrate 1101. The first and second substrates 102, 1101 may, for example, be or comprise silicon, epitaxial silicon, silicon-germanium, an SOI, or some other suitable semiconductor material. The first and second substrates 102, 1101 may, for example, each be lightly doped with the first doping type (e.g., p-type).

The first and second interconnect structures 1106, 1108 respectively comprise a dielectric structure 1114 and a plurality of conductive interconnects 1116, 1118, 1120 arranged in the dielectric structure 1114. The first and second interconnect structures 1106, 1108 are configured to facilitate electrical coupling between devices on and/or between the first and second IC chips 1102, 1104. The plurality of conductive interconnects 1116, 1118, 1120 include a plurality of conductive contacts 1116, a plurality of conductive wires 1118, and a plurality of conductive vias 1120. In various embodiments, the plurality of conductive contacts 1116 are in a corresponding inter-level dielectric (ILD) layer 1124 and contact etch stop layer (CESLs) 1126. The dielectric structure 1114 may include a plurality of dielectric layers vertically stacked with one another. The plurality of dielectric layers may, for example, be or comprise silicon dioxide, a low-k dielectric material, silicon nitride, silicon carbide, some other suitable dielectric material, or the like. The plurality of conductive interconnects 1116, 1118, 1120 may, for example, be or comprise aluminum, copper, tungsten, ruthenium, titanium nitride, tantalum nitride, some other conductive material, or any combination of the foregoing.

In various embodiments, the first and second interconnect structures 1106, 1108 further respectively comprise a plurality of bond pads 1123 in the dielectric structure 1114. The first IC chip 1102 is bonded to the second IC chip 1104 by way of a bonding interface 1122 that comprises both dielectric-to-dielectric bonds and conductor-to-conductor bonds. In various embodiments, the bond pads 1123 are configured to facilitate electrical coupling between the plurality of conductive interconnects 1116, 1118, 1120 of the first and second interconnect structures 1106, 1108.

The second IC chip 1104 comprises the plurality of logic devices 1110 arranged on a first surface of the second substrate 1101. The logic devices 1110 are separated from one another by an isolation structure 1112. The isolation structure 1112 may, for example, be a shallow trench isolation (STI) structure and may comprise a dielectric material (e.g., silicon dioxide, silicon nitride, silicon carbide, etc.). In some embodiments, the logic devices 1110 are or comprise metal-oxide semiconductor field-effect transistors (MOSFETs), fin field-effect transistors (finFETs), gate-all-around field-effect transistors (GAA FETs), some other suitable transistor, or any combination of the foregoing.

A trench isolation structure 1125 is arranged in the first substrate 102 and laterally surrounds the photodetector 104. A thickness t1 of the first substrate 102 may, or example, be approximately 3 micrometers (um), within a range of approximately 2.5 to 3.5 um, or some other suitable value. In various embodiments, the trench isolation structure 1125 extends through the thickness t1 of the first substrate 102. In various embodiments, the trench isolation structure 1125 continuously laterally wraps around an outer perimeter of the photodetector 104. The trench isolation structure 1125 is configured to increase electrical and/or optical isolation between the photodetector 104 and other devices (e.g., other photodetectors) arranged in and/or on the first substrate 102.

A conductive layer 1140 overlies a second surface 102b of the first substrate 102. The conductive layer 1140 extends into the second surface 102b of the first substrate 102 and has isolation segments on opposing sides of the photodetector 104 that at least partially form the trench isolation structure 1125. The isolation segments of the conductive layer 1140 may comprise inner surfaces defining one or more voids 1128. In some embodiments, the one or more voids 1128 are omitted. Further, the conductive layer 1140 comprises a protrusion 1140p that contacts the first substrate 102. The protrusion 1140p may be configured to bias a bulk of the first substrate 102 (e.g., may be configured as a grounding protrusion configured to ground the first substrate 102). The conductive layer 1140 may, for example, be or comprise aluminum, titanium, tungsten, titanium nitride, tantalum nitride, some other conductive material, or any combination of the foregoing.

A plurality of dielectric layers 1130-1138 overlie the second surface 102b of the first substrate 102. The plurality of dielectric layers 1130-1138 comprise a first dielectric layer 1130, a second dielectric layer 1132, a third dielectric layer 1134, a fourth dielectric layer 1136, and a fifth dielectric layer 1138. The first dielectric layer 1130 extends from the second surface 102b into one or more trenches defined by sidewalls of the first substrate 102. The first dielectric layer 1130 is arranged between the isolation segments of the conductive layer 1140 and the first substrate 102. The second dielectric layer 1132 overlies the first dielectric layer 1130. The third dielectric layer 1134 overlies the second dielectric layer 1132 and extends along sidewalls of the conductive layer 1140 into the one or more trenches. The first and third dielectric layers 1130, 1134 line the one or more trenches and partially define the trench isolation structure 1125. The third dielectric layer 1134 is arranged between the isolation segments of the conductive layer 1140 and the first substrate 102. The fourth dielectric layer 1136 overlies the third dielectric layer 1134 and the conductive layer 1140. The fifth dielectric layer 1138 overlies the fourth dielectric layer 1136. In some embodiments, the first and second dielectric layers 1130, 1132 may, for example, be or comprise a metal oxide, such as hafnium oxide, tantalum oxide, aluminum oxide, some other suitable dielectric material, or any combination of the foregoing. In various embodiments, the third, fourth, and fifth dielectric layers 1134, 1136, 1138 may, for example, be or comprise an oxide (e.g., silicon dioxide) and/or some other suitable dielectric material.

Further, a micro-lens 1142 is arranged on the fifth dielectric layer 1138 and directly overlies the photodetector 104. The micro-lens 1142 is configured to focus incident radiation towards the photodetector 104. In some embodiments, a light filter (not shown) is arranged between the micro-lens 1142 and the photodetector 104. The light filter is configured to selectively pass first light wavelengths while blocking other light wavelengths different from the first light wavelengths. The light filter may, for example, be configured as a color filter, an IR filter, or some other light filter.

FIG. 11B illustrates a cross-sectional view 1100b of some other embodiments of the image sensor of FIG. 11A, in which the absorption structure 108 of the photodetector 104 comprises a plurality of doped layers 602-606. The photodetector 104 is configured as illustrated and/or described in FIG. 6B.

FIG. 11C illustrates a cross-sectional view 1100c of some further embodiments of the image sensor of FIG. 11A, in which the absorption structure 108 of the photodetector 104 is arranged on the first surface 102a of the substrate 102. The photodetector 104 is configured as illustrated and/or described in FIG. 10A.

FIG. 11D illustrates a cross-sectional view 1100d of yet further embodiments of the image sensor of FIG. 11A, in which the absorption structure 108 of the photodetector is arranged on the first surface 102a of the substrate 102 and comprises a plurality of doped layers 602-606. The photodetector 104 is configured as illustrated and/or described in FIG. 10E.

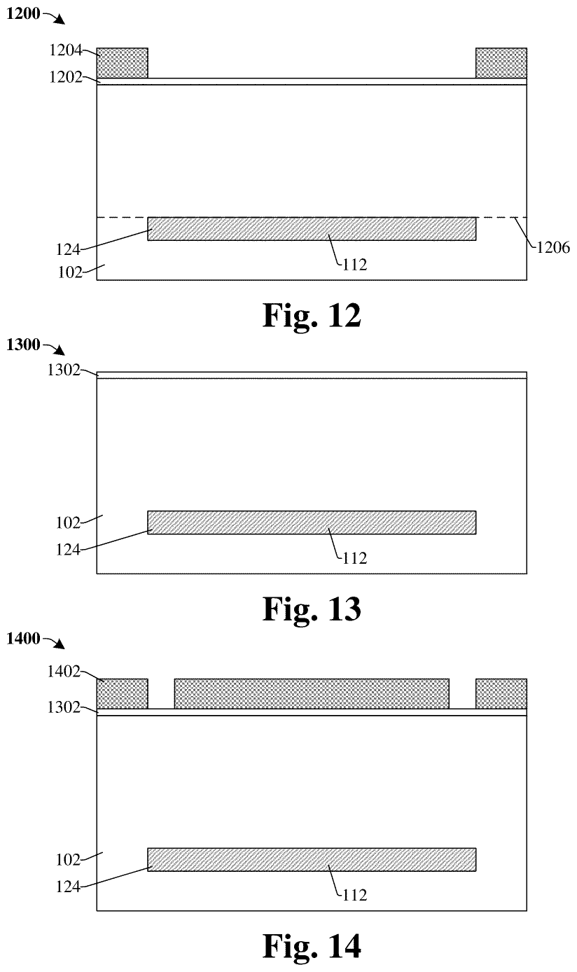

FIGS. 12-20 illustrate a series of cross-sectional views 1200-2000 of some embodiments of a method of forming an image sensor including a photodetector that comprises an absorption structure with a relatively high doping concentration. Although the cross-sectional views 1200-2000 shown in FIGS. 12-20 are described with reference to a method of forming the image sensor, it will be appreciated that the structures shown in FIGS. 12-20 are not limited to the method of formation but rather may stand alone separate of the method. Further, although FIGS. 12-20 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in cross-sectional view 1200 of FIG. 12, a substrate 102 is received and/or provided and a first dielectric layer 1202 may be formed on the substrate 102. Further, a lateral connection region 124 and a first avalanche well 112 are formed in the substrate 102. In some embodiments, the substrate 102 comprises a first material (e.g., silicon). In various embodiments, the substrate 102 may, for example, be or comprise monocrystalline silicon, epitaxial silicon, a silicon on insulator (SOI) substrate, silicon-germanium, one or more epitaxial layers, or some other suitable semiconductor substrate. The substrate 102 is intrinsic (e.g., intrinsic silicon) or is lightly doped with a first doping type (e.g., p-type). The light doping may, for example, correspond to a doping concentration equal to or less than approximately 1×10¹⁵ atoms/cm³, equal to or less than approximately 1×10¹⁶ atoms/cm³, equal to or less than approximately 5×10¹⁶ atoms/cm³, or some other suitable value.

The first dielectric layer 1202 may, for example, be or comprise silicon dioxide and/or some other suitable dielectric material. The first dielectric layer 1202 may, for example, be formed by chemical vapor deposition (CVD), physical vapor deposition (PVD), thermal oxidation, some other suitable growth or deposition process, or any combination of the foregoing.

In some embodiments, forming the lateral connection region 124 and the first avalanche well 112 includes: forming a first implant mask 1204 over the substrate 102; performing an ion implantation process to implant one or more dopants (e.g., phosphorus, arsenic, antimony, or the like) having a second doping type (e.g., n-type) into the substrate 102 with the first implant mask 1204 in place; and removing the first implant mask 1204. The first implant mask 1204 may, for example, be or comprise photoresist and/or some other suitable material. Further, after forming the lateral connection region 124 and the first avalanche well 112, the first dielectric layer 1202 may be removed, for example, by an etch process or some other suitable removal process.

In some embodiments, the substrate 102 comprises a base substrate (e.g., comprising silicon) and an upper semiconductor layer (e.g., comprising epitaxial silicon) over the base substrate. In various embodiments, the base substrate and the upper semiconductor layer may each be intrinsic (e.g., intrinsic silicon) or be lightly doped with a first doping type (e.g., p-type). In yet further embodiments, the lateral connection region 124 and the first avalanche well 112 may be formed in the base substrate and the upper semiconductor layer may be subsequently formed over the base substrate after forming the lateral connection region 124 and the first avalanche well 112. In such embodiments, the first dielectric layer 1202 and the first implant mask 1204 are formed over the base substrate and are removed before forming the upper semiconductor layer over the base substrate. In further embodiments, the base substrate may be a first portion of the substrate 102 at and below a dashed line 1206 and the upper semiconductor layer may be a second portion of the substrate 102 at and above the dashed line 1206.

As shown in cross-sectional view 1300 of FIG. 13, a second dielectric layer 1302 is formed on the substrate 102. The second dielectric layer 1302 may, for example, be or comprise silicon dioxide and/or some other suitable dielectric material. The second dielectric layer 1302 may, for example, be formed by CVD, PVD, thermal oxidation, some other suitable growth or deposition process, or any combination of the foregoing.

As shown in cross-sectional view 1400 of FIG. 14, a second implant mask 1402 is formed over the substrate 102. The second implant mask 1402 may, for example, be or comprise photoresist and/or some other suitable material.

As shown in cross-sectional view 1500 of FIG. 15, a vertical connection region 126 and a first contact region 128 are formed in the substrate 102. In some embodiments, the vertical connection region 126 has a pair of segments on opposing sides of the lateral connection region 124 and the first contact region 128 has a pair of segments over the vertical connection region 126. In some embodiments, forming the vertical connection region 126 and the first contact region 128 includes performing an ion implantation process to implant one or more dopants (e.g., phosphorus, arsenic, antimony, or the like) having the second doping type (e.g., n-type) into the substrate 102 with the second implant mask 1402 in place and removing the second implant mask 1402. In various embodiments, a doping concentration of the first contact region 128 is greater than a doping concentration of the vertical connection region 126 and/or a doping concentration of the lateral connection region 124.

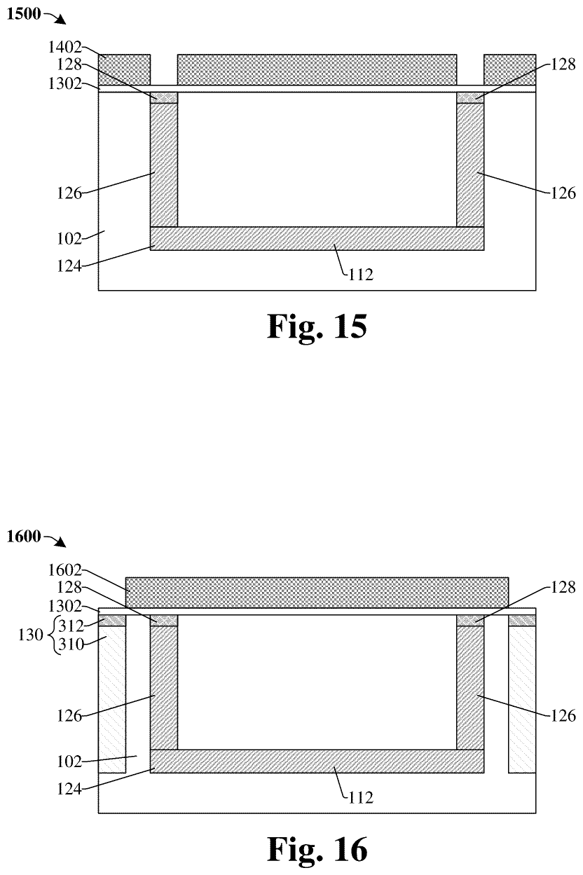

As shown in cross-sectional view 1600 of FIG. 16, an isolation structure 130 is formed in the substrate 102. In some embodiments, the isolation structure 130 is disposed on opposing sides of the vertical connection region 126, and comprises a first isolation region 310 and a second isolation region 312 over the first isolation region 310. In various embodiments, forming the isolation structure 130 includes: forming a third implant mask 1602 over the substrate 102; performing an ion implantation process to implant one or more dopants (e.g., boron, gallium, indium or the like) having the first doping type (e.g., p-type) into the substrate 102 with the third implant mask 1602 in place; and removing the third implant mask 1602. The third implant mask 1602 may, for example, be or comprise photoresist and/or some other suitable material. Further, after forming the isolation structure 130, the second dielectric layer 1302 may be removed, for example, by an etch process or some other suitable removal process.

As shown in cross-sectional view 1700 of FIG. 17, a patterning process is performed on the substrate 102 to form a recess 106 in the substrate 102. In some embodiments, the recess 106 is defined at least in part by opposing sidewalls and an upper surface of the substrate 102. In some embodiments, before performing the patterning process, a third dielectric layer 1702 is formed on the substrate 102. In various embodiments, the third dielectric layer 1702 may, for example, be or comprise silicon dioxide and/or some other suitable material. The third dielectric layer 1702 may, for example, be formed by CVD, PVD, thermal oxidation, or some other suitable growth or deposition process. In some embodiments, the patterning process includes forming a masking layer 1704 on the third dielectric layer 1702; performing an etching process on the substrate 102 and the third dielectric layer 1702 with the masking layer 1704 in place; and removing the masking layer 1704. In some embodiments, the etching process includes a dry etch (e.g., a reactive-ion etch, a plasma etch, or the like) or some other suitable etch process. The masking layer 1704 may, for example, be or comprise photoresist and/or some other suitable material.

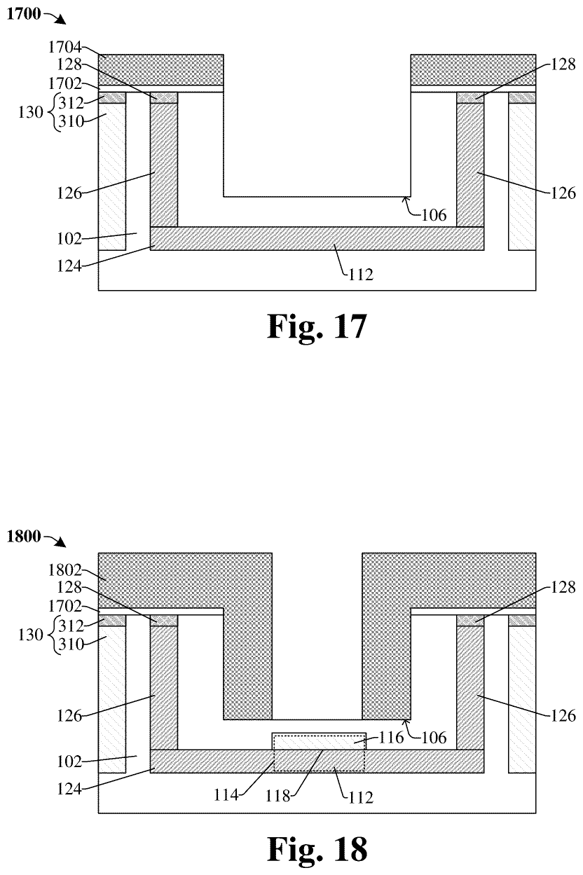

As shown in cross-sectional view 1800 of FIG. 18, a second avalanche well 116 is formed in the substrate 102. The second avalanche well 116 overlies the first avalanche well 112 and comprises the first doping type (e.g., p-type). The first avalanche well 112 meets the second avalanche well 116 at a PN junction 118. Further, the first avalanche well 112 and the second avalanche well 116 form or define an avalanche region 114. In some embodiments, forming the second avalanche well 116 includes: forming a fourth implant mask 1802 over the substrate 102; performing an ion implantation process to implant one or more dopants (e.g., boron, gallium, indium or the like) having the first doping type (e.g., p-type) into the substrate 102 with the fourth implant mask 1802 in place; and removing the fourth implant mask 1802. The fourth implant mask 1802 may, for example, be or comprise photoresist and/or some other suitable material. In some embodiments, after forming the second avalanche well 116, an annealing process (e.g., a rapid thermal anneal (RTA)) is performed to activate dopants implanted into the substrate 102. In various embodiments, the second avalanche well 116 may be formed in the substrate 102 before forming the recess 106 (e.g., after forming the vertical connection region 126 in FIG. 15 and before forming the recess 106 in FIG. 17).

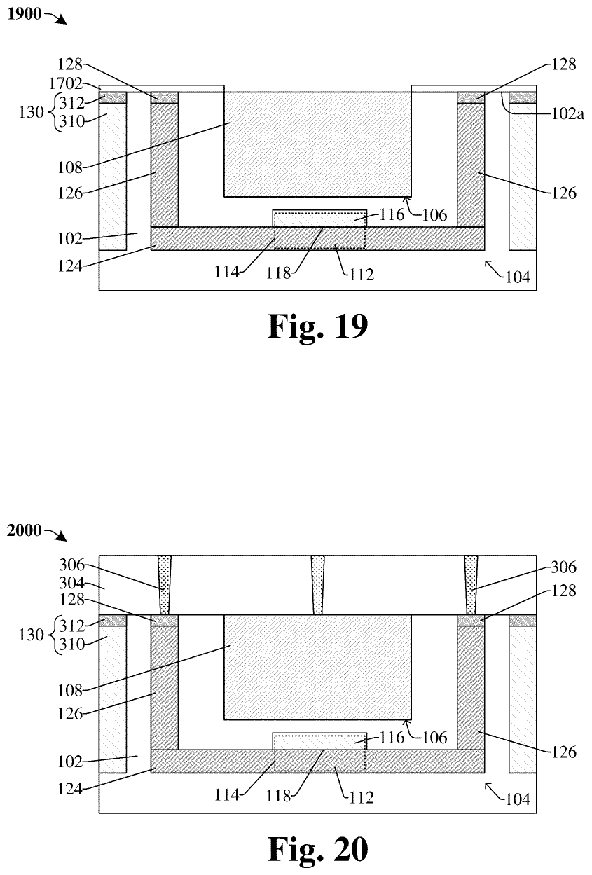

As shown in cross-sectional view 1900 of FIG. 19, an absorption structure 108 is formed in the recess 106. In some embodiments, the absorption structure 108 directly contacts one or more surfaces of the substrate 102 defining the recess 106. In various embodiments, the absorption structure 108 comprises a second material (e.g., germanium) different from the first material (e.g., silicon). In some embodiments, the absorption structure 108 is heavily doped with first dopants (e.g., boron, gallium, etc.) having the first doping type (e.g., p-type). For example, at least a majority of a volume (e.g., at least 50% of the volume) of the absorption structure 108 is heavily doped with the first doping type. Heavily doped may, for example, correspond to a doping concentration greater than approximately 2×10¹⁸ atoms/cm³ or some other suitable value. In some embodiments, the doping concentration of the absorption structure 108 is greater than that of the first avalanche well 112, the vertical connection region 126, the lateral connection region 124, the second avalanche well 116, and/or a bulk of the substrate 102. In various embodiments, the absorption structure 108 is formed with an upper surface aligned with a first surface 102a of the substrate 102. In further embodiments, the absorption structure 108 is formed with an upper surface that is arranged below the first surface 102a of the substrate 102. The third dielectric layer 1702 may be removed, for example, by an etch process after forming the absorption structure 108.

The absorption structure 108 may, for example, be formed by an epitaxial process such as MBE, CVD, VPE, LPE, or some other suitable process. In some embodiments, the absorption structure 108 may be formed by an epitaxial process (e.g., CVD or some other suitable process) with: a precursor gas (e.g., GeH₄); a temperature within a range of approximately 350 to 900 degrees Celsius; and a pressure within a range of approximately 1 to 60 torr. In yet further embodiments, the epitaxial process includes an additional dopant precursor gas (e.g., diaborane (B₂H₆) or the like), such that the absorption structure 108 is in-situ doped with the first doping type (e.g., p-type) having the heavy doping concentration. In such embodiments, a flow of the additional dopant precursor gas during the epitaxial process may be adjusted to form the absorption structure 108 with a suitable doping profile and/or doping concentration. In yet further embodiments, the absorption structure 108 may be grown or deposited (e.g., by the epitaxial process) as intrinsic (e.g., undoped) and one or more ion implantation process(es) utilizing one or more implant masks are performed such that the absorption structure 108 is heavily doped with the first doping type (e.g., p-type).

A doping concentration of the absorption structure 108 may, for example, be greater than approximately 2×10¹⁸ atoms/cm³, equal to or greater than approximately 1×10¹⁹ atoms/cm³, within a range of approximately 2×10¹⁸ to 5×10²⁰ atoms/cm³, or some other suitable value. The absorption structure 108 and the avalanche region 114 at least in part form or define a photodetector 104. The absorption structure 108 being heavily doped with the first doping type (e.g., p-type) reduces dark current in the photodetector 104. Further the absorption structure 108 being heavily doped with the first doping type (e.g., p-type) facilitates decreasing fabrication complexity of the photodetector 104 compared to other photodetectors. For example, the photodetector 104 may be formed without a contact region and/or a guard region in and/or on the absorption structure 108, and/or may be formed without one or more interlayers between the absorption structure 108 and the substrate 102. As a result, costs and/or time associated with forming the photodetector 104 may be reduced.

As shown in cross-sectional view 2000 of FIG. 20, a dielectric structure 304 and a plurality of conductive contacts 306 are formed over the substrate 102. The dielectric structure 304 may, for example, be formed by one or more CVD processes, PVD processes, atomic layer deposition (ALD) processes, or some other suitable growth or deposition processes. The plurality of conductive contacts 306 are formed in the dielectric structure 304.

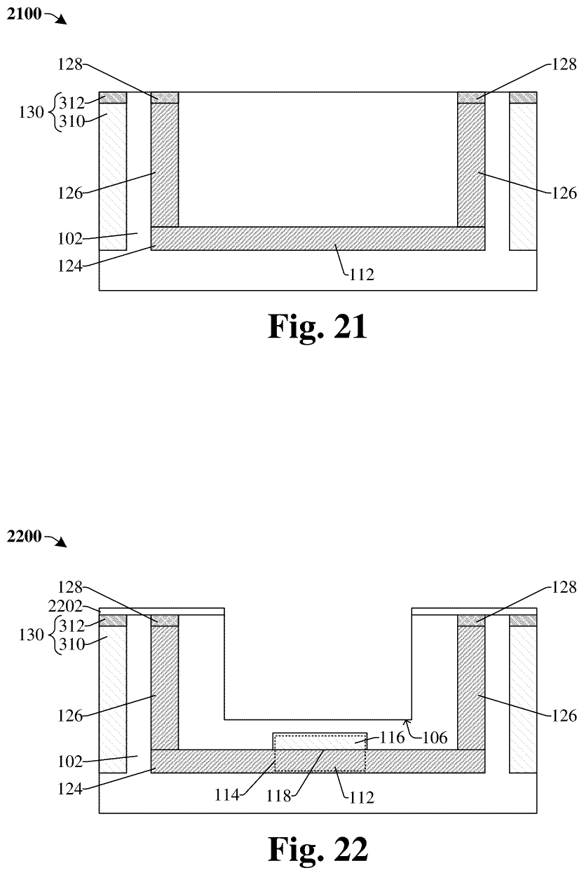

FIGS. 21-24 illustrate a series of cross-sectional views 2100-2400 of some other embodiments of a method for forming an image sensor including a photodetector that comprises an absorption structure with a relatively high doping concentration. Although the cross-sectional views 2100-2400 shown in FIGS. 21-24 are described with reference to a method of forming the image sensor, it will be appreciated that the structures shown in FIGS. 21-24 are not limited to the method of formation but rather may stand alone separate of the method. Further, although FIGS. 21-24 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in cross-sectional view 2100 of FIG. 21, a lateral connection region 124, a first avalanche well 112, a vertical connection region 126, a first contact region 128, and an isolation structure 130 are formed in a substrate 102. The structure of FIG. 21 may, for example, be formed by the acts illustrated and/or described in FIGS. 12-16.

As shown in cross-sectional view 2200 of FIG. 22, a first dielectric layer 2202 is formed on the substrate 102, a recess 106 is formed in the substrate 102, and a second avalanche well 116 is formed in the substrate 102. The first dielectric layer 2202 may, for example, be or comprise silicon dioxide or some other suitable material. The recess 106 may, for example, be formed by the acts illustrated and/or described in FIG. 17. The second avalanche well 116 may, for example, be formed by the acts illustrated and/or described in FIG. 18.

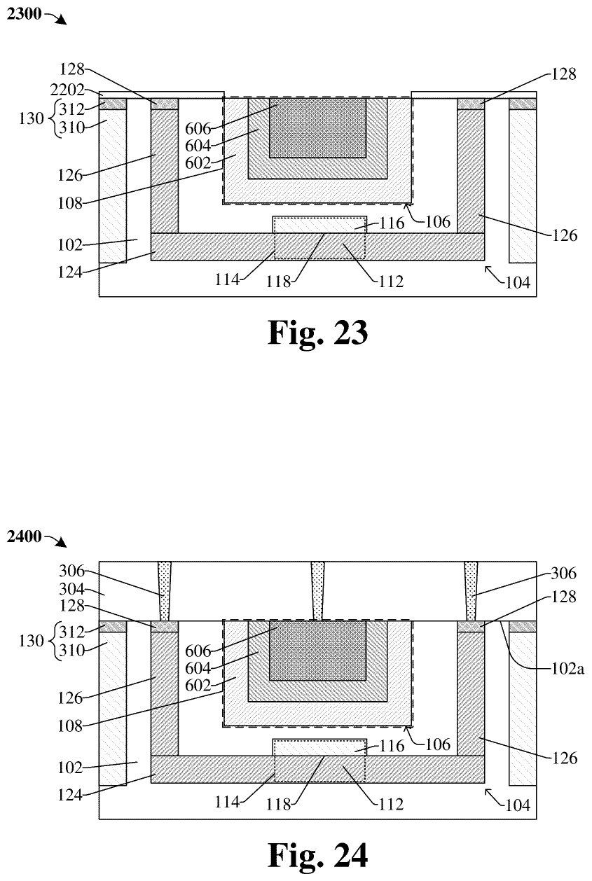

As shown in cross-sectional view 2300 of FIG. 23, an absorption structure 108 is formed in the recesses 106. In some embodiments, the absorption structure 108 comprises a plurality of doped layers 602-606. Each of the doped layers 602-606 comprise the first doping type with different doping concentrations from one another. In various embodiments, one or more of the doped layers 602-606 are heavily doped with the first doping type, thereby reducing dark current in the photodetector 104. The plurality of doped layers 602-606 includes a first doped layer 602, a second doped layer 604, and a third doped layer 606.

In some embodiments, a process for forming the absorption structure 108 comprises: performing a first epitaxial process (e.g., MVD, CVD, VPE, LPE, etc.) to form the first doped layer 602 lining the recess 106; performing a second epitaxial process (e.g., MVD, CVD, VPE, LPE, etc.) to from the second doped layer 604 on the first doped layer 602; and performing a third epitaxial process (e.g., MVD, CVD, VPE, LPE, etc.) to form the third doped layer 606 on the second doped layer 604. In various embodiments, the first, second, and third epitaxial processes respectively are performed with: a precursor gas (e.g., GeH₄); an additional dopant precursor gas (e.g., diaborane (B₂H₆) or the like); a temperature within a range of approximately 350 to 900 degrees Celsius; and a pressure within a range of approximately 1 to 60 torr. As a result, the plurality of doped layers 602-606 are in-situ doped with the first doping type (e.g., p-type). Further, a flow rate of the additional dopant precursor gas is different during the first, second, and third epitaxial processes, such that the plurality of doped layers 602-606 may have different doping concentrations and/or doping profiles from one another. In yet further embodiments, the absorption structure 108 may be formed by a single epitaxial process, where a flow of the additional dopant precursor gas (e.g., diaborane (B₂H₆) or the like) is varied at different times during the single epitaxial process to form the plurality of doped layers 602-606 with the varying doping concentrations. In such embodiments, the plurality of doped layers 602-606 may each be a corresponding doped region of the absorption structure 108 instead of being individual epitaxial layers.

In yet further embodiments, a process for forming the absorption structure 108 comprises performing a single epitaxial process (e.g., MVD, CVD, VPE, LPE, etc.) to form and/or grow the second material (e.g., germanium) in the recess and subsequently performing a plurality of selective ion implantation processes to form the plurality of doped layers 602-606. In such embodiments, the plurality of doped layers 602-606 may each be an individual doped region of the absorption structure 108 having different doping concentrations from one another. The plurality of selective ion implantation processes may comprise: performing one or more first selective ion implantation processes according to one or more first implant masks to form the first doped layer 602; performing one or more second selective ion implantation processes according to one or more second implant masks to form the second doped layer 604; and performing one or more second selective ion implantation processes to form the third doped layer 606.

In some embodiments, one or more of the doped layers 602-606 has/have a doping concentration that is greater than approximately 2×10¹⁸ atoms/cm³. In yet further embodiments, the doping concentrations of the plurality of doped layers 602-606 are configured such that at least a majority of the volume (e.g., at least 50% of the volume) of the absorption structure 108 is highly doped (e.g., having a doping concentration greater than approximately 2×10¹⁸ atoms/cm³). The first dielectric layer 2202 may, for example, be removed by an etching process after forming the absorption structure 108. Further, after forming the absorption structure 108, a planarization process (e.g., an etch process, a chemical mechanical planarization (CMP) process, etc.) may be performed on the plurality of doped layers 602-606 such that top surfaces of the plurality of doped layers 602-606 are aligned with one another.

As shown in cross-sectional view 2400 of FIG. 24, a dielectric structure 304 and a plurality of conductive contacts 306 are formed on the substrate 102.

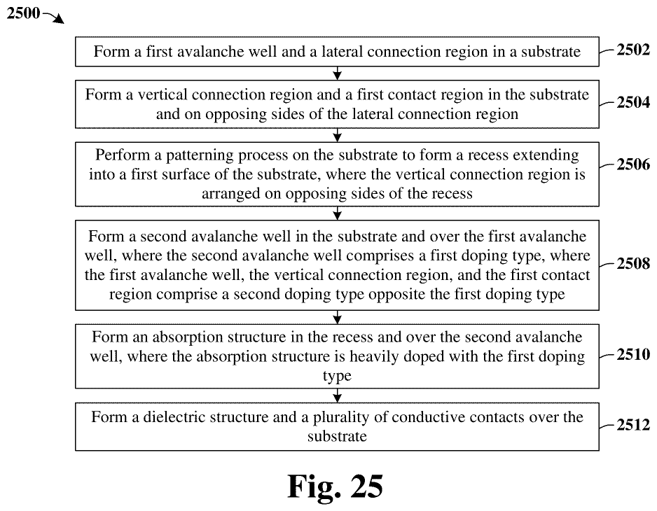

FIG. 25 illustrates a block diagram 2500 of some embodiments of a method of forming an image sensor including a photodetector that comprises an absorption structure with a relatively high doping concentration. Although the block diagram 2500 is illustrated and/or described as a series of acts or events, it will be appreciated that the illustrated ordering of such acts or events is not to be interpreted in a limiting sense. For example, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 2502, a first avalanche well and a lateral connection region are formed in a substrate. FIG. 12 illustrates a cross-sectional view 1300 corresponding to some embodiments of act 2502.

At act 2504, a vertical connection region and a first contact region are formed in the substrate on opposing sides of the lateral connection region. FIGS. 14 and 15 illustrate cross-sectional views 1400 and 1500 corresponding to some embodiments of act 2504.

At act 2506, a patterning process is performed on the substrate to form a recess extending into a first surface of the substrate. The vertical connection region is arranged on opposing sides of the recess. FIG. 17 illustrates a cross-sectional view 1700 corresponding to some embodiments of act 2506.

At act 2508, a second avalanche well is formed in the substrate over the first avalanche well. The second avalanche well comprises a first doping type. The first avalanche well, the vertical connection region, and the first contact region comprise a second doping type opposite the first doping type. FIG. 18 illustrates a cross-sectional view 1800 corresponding to some embodiments of act 2508.

At act 2510, an absorption structure is formed in the recess over the second avalanche well, where the absorption structure is heavily doped with the first doping type. FIG. 19 illustrates a cross-sectional view 1900 corresponding to some embodiments of act 2510. FIG. 23 illustrates a cross-sectional view 2300 corresponding to some other embodiments of act 2510.

At act 2512, a dielectric structure and a plurality of conductive contacts are formed over the substrate. FIG. 24 illustrates a cross-sectional view 2400 corresponding to some embodiments of act 2512.

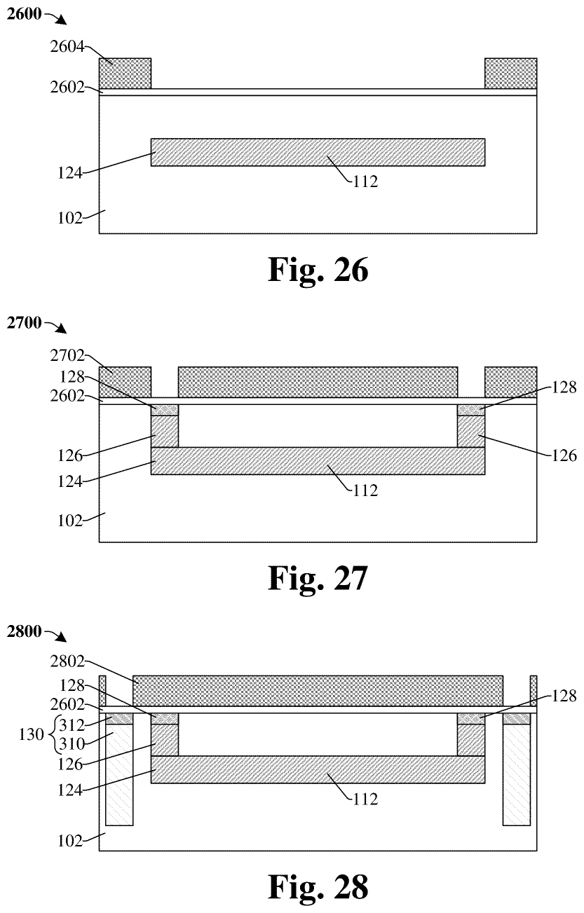

FIGS. 26-32 illustrate a series of cross-sectional views 2600-3200 of some further embodiments of a method of forming an image sensor including a photodetector that comprises an absorption structure with a relatively high doping concentration. Although the cross-sectional views 2600-3200 shown in FIGS. 26-32 are described with reference to a method of forming the image sensor, it will be appreciated that the structures shown in FIGS. 26-32 are not limited to the method of formation but rather may stand alone separate of the method. Further, although FIGS. 26-32 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in cross-sectional view 2600 of FIG. 26, a first dielectric layer 2602 is formed on a substrate 102, and a lateral connection region 124 and a first avalanche well 112 are formed in a substrate 102. The first dielectric layer 2602 may, for example, be or comprise silicon dioxide and/or some other suitable dielectric material. The first dielectric layer 2602 may, for example, be formed by CVD, PVD, thermal oxidation, or some other suitable growth or deposition process. In some embodiments, the substrate 102 comprises a first material (e.g., silicon). In various embodiments, the substrate 102 may, for example, be or comprise monocrystalline silicon, epitaxial silicon, a SOI substrate, silicon-germanium, or some other suitable semiconductor substrate. The substrate 102 is intrinsic (e.g., intrinsic silicon) or is lightly doped with a first doping type (e.g., p-type). The light doping may, for example, correspond to a doping concentration equal to or less than approximately 1×10¹⁵ atoms/cm³ or some other suitable value.

In some embodiments, forming the lateral connection region 124 and the first avalanche well 112 includes: forming a first implant mask 2604 over the substrate 102; performing an ion implantation process to implant one or more dopants (e.g., phosphorus, arsenic, antimony, or the like) having a second doping type (e.g., n-type) into the substrate 102 with the first implant mask 2604 in place; and removing the first implant mask 2604. The first implant mask 2604 may, for example, be or comprise photoresist and/or some other suitable material.

As shown in cross-sectional view 2700 of FIG. 27, a vertical connection region 126 and a first contact region 128 are formed in the substrate 102. In some embodiments, forming the vertical connection region 126 and the first contact region 128 includes: forming a second implant mask 2702 over the substrate 102; performing an ion implantation process to implant one or more dopants (e.g., phosphorus, arsenic, antimony, or the like) having the second doping type (e.g., n-type) into the substrate 102 with the second implant mask 2702 in place; and removing the second implant mask 2702.

As shown in cross-sectional view 2800 of FIG. 28, an isolation structure 130 is formed in the substrate 102. In some embodiments, forming the isolation structure 130 includes: forming a third implant mask 2802 over the substrate 102; performing an ion implantation process to implant one or more dopants (e.g., boron, gallium, indium or the like) having the first doping type (e.g., p-type) into the substrate 102 with the third implant mask 2802 in place; and removing the third implant mask 2802. The third implant mask 2802 may, for example, be or comprise photoresist and/or some other suitable material.

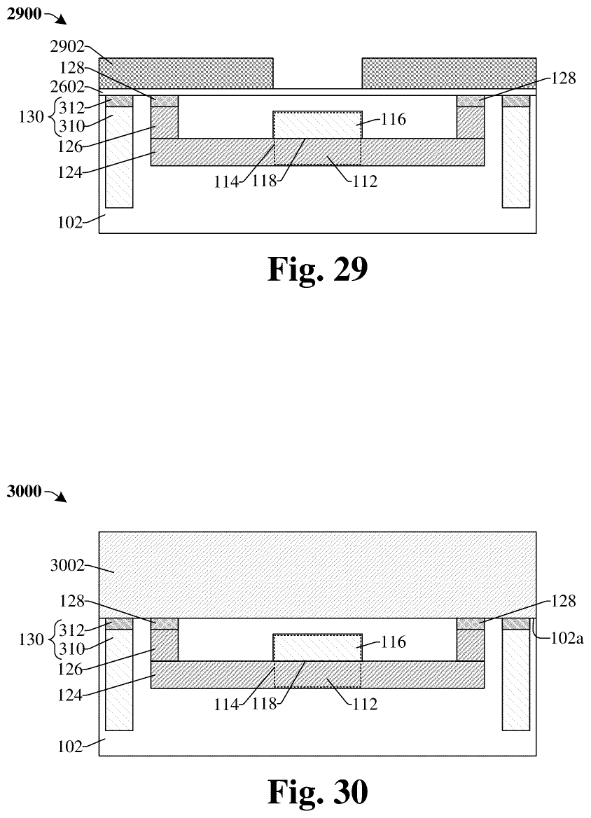

As shown in cross-sectional view 2900 of FIG. 29, a second avalanche well 116 is formed in the substrate 102 over the first avalanche well 112. The second avalanche well 116 comprises the first doping type (e.g., p-type). The first avalanche well 112 meets the second avalanche well 116 at a PN junction 118. Further, the first avalanche well 112 and the second avalanche well 116 form or define an avalanche region 114. In some embodiments, forming the second avalanche well 116 includes: forming a fourth implant mask 2902 over the substrate 102; performing an ion implantation process to implant one or more dopants (e.g., boron, gallium, indium or the like) having the first doping type (e.g., p-type) into the substrate 102 with the fourth implant mask 2902 in place; and removing the fourth implant mask 2902. The fourth implant mask 2902 may, for example, be or comprise photoresist and/or some other suitable material. In some embodiments, after forming the second avalanche well 116, an annealing process (e.g., a RTA) is performed to activate dopants implanted into the substrate 102.

As shown in cross-sectional view 3000 of FIG. 30, an absorption layer 3002 is formed on a first surface 102a of the substrate 102. The absorption layer 3002 comprises a second material (e.g., germanium different from the first material (e.g., silicon). In some embodiments, the absorption layer 3002 is heavily doped with first dopants (e.g., boron, gallium, etc.) having the first doping type (e.g., p-type). For example, at least a majority of a volume (e.g., at least 50% of the volume) of the absorption layer 3002 is heavily doped with the first doping type. Heavily doped may, for example, correspond to a doping concentration greater than approximately 2×10¹⁸ atoms/cm³ or some other suitable value. In various embodiments, the absorption layer 3002 may be formed by the acts and/or processes illustrated and/or described in regards to forming the absorption structure 108 of FIG. 19.

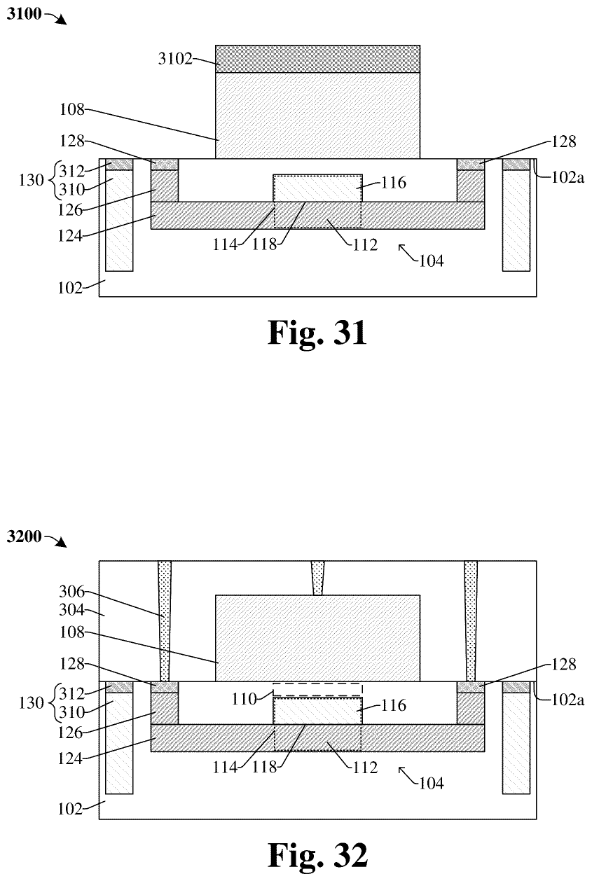

As shown in cross-sectional view 3100 of FIG. 31, a patterning process is performed on the absorption layer (3002 of FIG. 30), thereby forming or defining an absorption structure 108. The absorption structure 108 and the avalanche region 114 at least in part form or define a photodetector 104. In some embodiments, the patterning process includes forming a masking layer 3102 on the absorption layer (3002 of FIG. 30); performing an etching process on the absorption layer (3002 of FIG. 30) with the masking layer 3102 in place; and removing the masking layer 3102. In some embodiments, the etching process includes a dry etch (e.g., a reactive-ion etch, a plasma etch, or the like) or some other suitable etch process. The masking layer 3102 may, for example, be or comprise photoresist and/or some other suitable material.

As shown in cross-sectional view 3200 of FIG. 32, a dielectric structure 304 and a plurality of conductive contacts 306 are formed over the substrate 102 and the absorption structure 108.

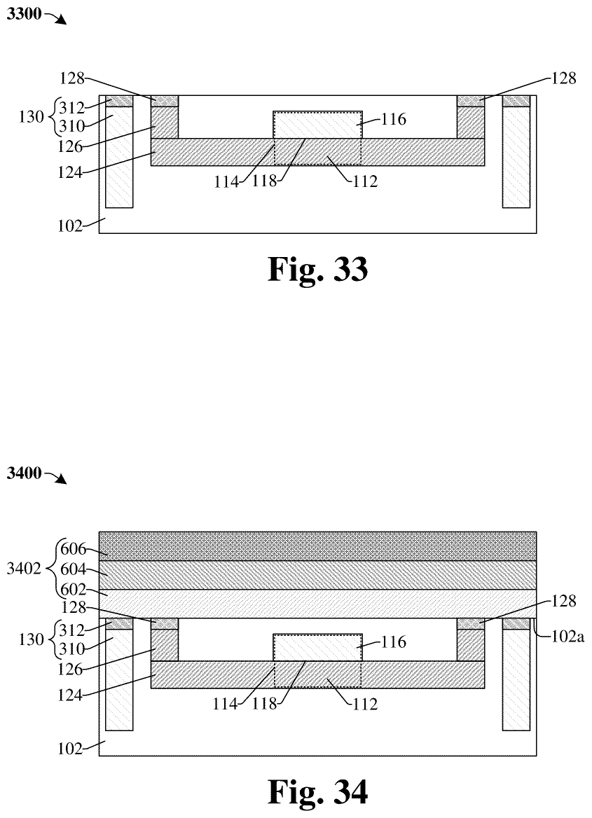

FIGS. 33-36 illustrate a series of cross-sectional views 3300-3600 of yet further embodiments of a method for forming an image sensor including a photodetector that comprises an absorption structure with a relatively high doping concentration. Although the cross-sectional views 3300-3600 shown in FIGS. 33-36 are described with reference to a method of forming the image sensor, it will be appreciated that the structures shown in FIGS. 33-36 are not limited to the method of formation but rather may stand alone separate of the method. Further, although FIGS. 33-36 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in cross-sectional view 3300 of FIG. 33, a lateral connection region 124, a first avalanche well 112, a vertical connection region 126, a first contact region 128, a second avalanche well 116, and an isolation structure 130 are formed in a substrate 102. The structure of FIG. 33 may, for example, be formed by the acts illustrated and/or described in FIGS. 26-29.

As shown in cross-sectional view 3400 of FIG. 34, a stack of absorption layers 3402 is formed on a first surface 102a of the substrate 102. In some embodiments, the stack of absorption layers 3402 comprises a plurality of doped layers 602-606. Each of the doped layers in the plurality of doped layers 602-606 comprise a second material (e.g., germanium) and the first doping type (e.g., p-type) with varying doping concentrations from one another. The plurality of doped layers 602-606 includes a first doped layer 602, a second doped layer 604, and a third doped layer 606.

In some embodiments, the plurality of doped layers 602-606 may be formed as illustrated and/or described in FIG. 23. For example, the doped layers 602-606 may respectively be formed by an individual epitaxial process that includes in-situ doping of the first doping type. In another embodiments, the plurality of doped layers 602-606 may be formed by a single epitaxial process that includes varying a flow of a dopant precursor gas during the single epitaxial process. In further embodiments, the plurality of doped layers 602-606 includes performing a single epitaxial process to form or grow the second material (e.g., germanium) on the substrate 102 and performing one or more ion implantation processes.

In some embodiments, one or more of the doped layers 602-606 has/have a doping concentration that is greater than approximately 2×10¹⁸ atoms/cm³. In yet further embodiments, the doping concentrations of the plurality of doped layers 602-606 are configured such that at least a majority of the volume (e.g., at least 50% of the volume) of the absorption structure 108 is highly doped (e.g., having a doping concentration greater than approximately 2×10¹⁸ atoms/cm³).

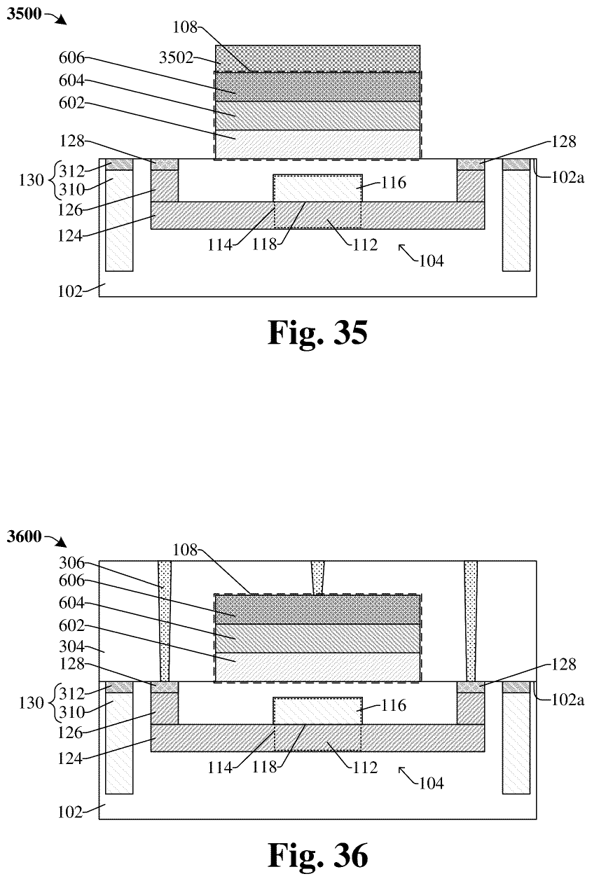

As shown in cross-sectional view 3500 of FIG. 35, a patterning process is performed on the stack of absorption layers (3402 of FIG. 34), thereby forming or defining an absorption structure 108 on the substrate 102. The absorption structure 108 comprises the plurality of doped layers 602-606. In some embodiments, the patterning process includes forming a masking layer 3502 on the stack of absorption layers (3402 of FIG. 34); performing an etching process on the stack of absorption layers (3402 of FIG. 34) with the masking layer 3502 in place; and removing the masking layer 3502. In some embodiments, the etching process includes a dry etch (e.g., a reactive-ion etch, a plasma etch, or the like) or some other suitable etch process. The masking layer 3502 may, for example, be or comprise photoresist and/or some other suitable material.

As shown in cross-sectional view 3600 of FIG. 36, a dielectric structure 304 and a plurality of conductive contacts 306 are formed over the substrate 102 and the absorption structure 108.

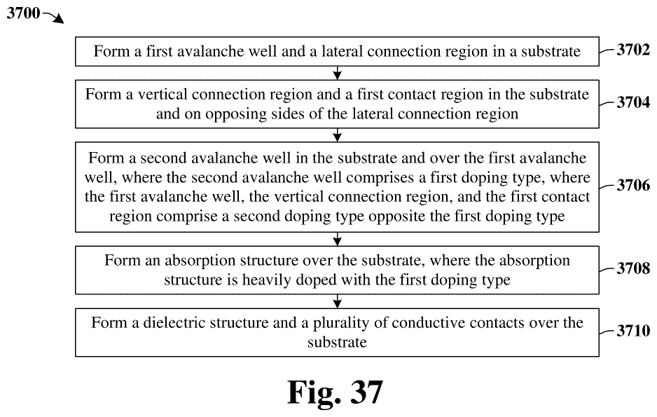

FIG. 37 illustrates a block diagram 3700 of some other embodiments of a method of forming an image sensor including a photodetector that comprises an absorption structure with a relatively high doping concentration. Although the block diagram 3700 is illustrated and/or described as a series of acts or events, it will be appreciated that the illustrated ordering of such acts or events is not to be interpreted in a limiting sense. For example, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 3702, a first avalanche well and a lateral connection region are formed in a substrate. FIG. 26 illustrates a cross-sectional view 2600 corresponding to some embodiments of act 3702.

At act 3704, a vertical connection region and a first contact region are formed in the substrate on opposing sides of the lateral connection region. FIG. 27 illustrates a cross-sectional view 2700 corresponding to some embodiments of act 3704.

At act 3706, a second avalanche well is formed in the substrate over the first avalanche well. The second avalanche well comprises a first doping type. The first avalanche well, the vertical connection region, and the first contact region comprise a second doping type opposite the first doping type. FIG. 29 illustrates a cross-sectional view 2900 corresponding to some embodiments of act 3706.

At act 3708, an absorption structure is formed over the substrate, where the absorption structure is heavily doped with the first doping type. FIGS. 30 and 31 illustrate cross-sectional views 3000 and 3100 corresponding to some embodiments of act 3708. FIGS. 34 and 35 illustrate cross-sectional views 3400 and 3500 corresponding to some other embodiments of act 3708.

At act 3710, a dielectric structure and a plurality of conductive contacts are formed over the substrate. FIG. 32 illustrates a cross-sectional view 3200 corresponding to some embodiments of act 3710.

Accordingly, in some embodiments, the present disclosure relates to an image sensor comprising a photodetector including an absorption structure within and/or on a substrate, the absorption structure is heavily doped with a first doping type (e.g., p-type).

In some embodiments, the present application provides a device, including: a substrate including a first material; an absorption structure on a surface of the substrate and including a second material having a smaller bandgap than the first material, wherein the absorption structure has a first doping concentration of a first doping type, wherein the first doping concentration of the absorption structure is greater than a doping concentration of a region of the substrate abutting the absorption structure; a first well region in the substrate and offset from the absorption structure, wherein the first well region comprises a second doping type different from the first doping type; and a second well region in the substrate and arranged between the first well region and the absorption structure, wherein the second well region comprises the first doping type. In some embodiments, the first doping concentration of at least 50 percent of a volume of the absorption structure is greater than approximately 2×10¹⁸ atoms/cm³. In some embodiments, the first doping concentration of the absorption structure is substantially constant across both a width and a thickness of the absorption structure. In some embodiments, the absorption structure has a gradient doping profile over a thickness of the absorption structure. In some embodiments, the second well region meets the first well region at a PN junction, wherein a doping concentration of the first well region and a doping concentration of the second well region are both less than the first doping concentration. In some embodiments, the first well region underlies the absorption structure and the second well region is spaced vertically between the first well region and a bottom surface of the absorption structure, wherein the device further includes: a vertical connection region in the substrate and on opposing sides of the absorption structure, wherein the vertical connection region abuts a top of the first well region and laterally wraps around the absorption structure, wherein the vertical connection region laterally wraps around the absorption structure and comprises the second doping type; and a first contact region in the substrate and over the vertical connection region, wherein the first contact region comprises the second doping type, wherein a doping concentration of the first contact region is greater than the first doping concentration. In some embodiments, the second well region continuously extends from the first well region into the absorption structure, wherein at least a portion of the second well region is arranged in the absorption structure. In some embodiments, the absorption structure includes a first doped region having the first doping concentration, a second doped region having a second doping concentration of the first doping type, and a third doped region having a third doping concentration of the first doping type, wherein the second doped region is arranged between the first doped region and the third doped region, wherein the first, second, and third doping concentrations are different from one another, wherein the second doping concentration and the third doping concentration are greater than the doping concentration of the region of the substrate, wherein at least one of the first, second, and third doping concentrations is greater than approximately 2×10¹⁸ atoms/cm³. In some embodiments, the first doping concentration is less than the second doping concentration and the third doping concentration is greater than the second doping concentration, wherein the first doped region occupies a first volume of the absorption structure and the second doped region occupies a second volume of the absorption structure less than the first volume. In some embodiments, the device further includes a capping layer over a top surface of the absorption structure, wherein the capping layer comprises the second material and has the first doping type, wherein a doping concentration of the capping layer is greater than the first doping concentration.

In further embodiments, the present application provides a method, including: forming a first well region in a substrate, wherein the substrate includes silicon; forming a second well region in the substrate and abutting the first well region; and forming a germanium structure on a surface of the substrate, wherein the second well region is arranged between the first well region and the germanium structure, wherein the germanium structure and the second well region have a first doping type, wherein the first well region has a second doping type opposite the first doping type, wherein a doping concentration of the germanium structure is greater than doping concentrations of the first well region and the second well region. In some embodiments, a dopant of the first doping type includes boron or gallium, wherein the doping concentration of at least half a volume of the germanium structure is greater than approximately 2×10¹⁸ atoms/cm³, wherein a bulk of the substrate has the first doping type, wherein a doping concentration of the bulk of the substrate is less than the doping concentrations of the first well region and the second well region. In some embodiments, the method further includes etching the substrate to form a recess in the substrate, wherein the recess is defined by opposing sidewalls and the surface of the substrate, wherein the germanium structure is formed in the recess and contacts the opposing sidewalls and the surface of the substrate. In some embodiments, the first well region includes a pair of segments disposed on opposing sides of the recess, wherein a bottom of the first well region is arranged above a bottom surface of the germanium structure, wherein the second well region is disposed laterally between the pair of segments of the first well region and the germanium structure. In some embodiments, the method further includes forming a vertical connection region in the substrate and on opposing ends of the first well region, wherein the vertical connection region has the second doping type, wherein the bottom surface of the germanium structure is vertically above a top of the vertical connection region. In some embodiments, the method further includes forming a germanium capping layer over a top surface and along opposing sidewalls of the germanium structure, wherein the germanium capping layer has the first doping type and has a doping concentration greater than the doping concentration of the germanium structure. In some embodiments, the germanium structure includes a first doped layer, a second doped layer over the first doped layer, and a third doped layer over the second doped layer, wherein the doping concentration of the germanium structure changes across the first, second, and third doped layers, wherein in cross-sectional view the first doped layer and the second doped layer are respectively U-shaped, wherein the second doped layer extends along opposing sidewalls and a lower surface of the third doped layer.

In yet further embodiments, the present application provides a method, including: performing a first implantation process to form a lateral connection region in a substrate, wherein the substrate includes a first material, wherein a bulk of the substrate has a first doping type and the lateral connection region has a second doping type opposite the first doping type; performing a second implantation process to form a first contact region and a vertical connection region in the substrate, wherein the first contact region overlies the vertical connection region and the vertical connection region is on opposing sides of the lateral connection region, wherein the first contact region and the vertical connection region have the second doping type; performing a third implantation process to form an avalanche well in the substrate and over the lateral connection region, wherein the avalanche well has the first doping type; and forming an absorption structure on a surface of the substrate, wherein the absorption structure includes a second material different from the first material, wherein the absorption structure has the first doping type and has a first doping concentration that is greater than approximately 2×10¹⁸ atoms/cm³. In some embodiments, forming the absorption structure includes: forming a first doped layer over the substrate; forming a second doped layer over the first doped layer; and forming a third doped layer over the second doped layer, wherein one or more of the first, second, and third doped layers have the first doping concentration, wherein at least an individual one of the first, second, and third doped layers has a second doping concentration less than the first doping concentration. In some embodiments, the method further includes etching the substrate to form a recess extending into the substrate, wherein the first doped layer lines opposing sidewalls and the surface of the substrate defining the recess, wherein the second doped layer is arranged along interior surfaces of the first doped layer, and the third doped layer is arranged along interior surfaces of the second doped layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a substrate comprising a first material;
an absorption structure on a surface of the substrate and comprising a second material having a smaller bandgap than the first material, wherein the absorption structure has a first doping concentration of a first doping type, wherein the first doping concentration of the absorption structure is greater than a doping concentration of a region of the substrate abutting the absorption structure;
a first well region in the substrate and offset from the absorption structure, wherein the first well region comprises a second doping type different from the first doping type; and
a second well region in the substrate and arranged between the first well region and the absorption structure, wherein the second well region comprises the first doping type.

2. The device of claim 1, wherein the first doping concentration of at least 50 percent of a volume of the absorption structure is greater than approximately 2×10¹⁸ atoms/cm³.

3. The device of claim 1, wherein the first doping concentration of the absorption structure is substantially constant across both a width and a thickness of the absorption structure.

4. The device of claim 1, wherein the absorption structure has a gradient doping profile over a thickness of the absorption structure.

5. The device of claim 1, wherein the second well region meets the first well region at a PN junction, wherein a doping concentration of the first well region and a doping concentration of the second well region are both less than the first doping concentration.

6. The device of claim 5, wherein the first well region underlies the absorption structure and the second well region is spaced vertically between the first well region and a bottom surface of the absorption structure, wherein the device further comprises:
a vertical connection region in the substrate and on opposing sides of the absorption structure, wherein the vertical connection region abuts a top of the first well region and laterally wraps around the absorption structure, wherein the vertical connection region laterally wraps around the absorption structure and comprises the second doping type; and
a first contact region in the substrate and over the vertical connection region, wherein the first contact region comprises the second doping type, wherein a doping concentration of the first contact region is greater than the first doping concentration.

7. The device of claim 5, wherein the second well region continuously extends from the first well region into the absorption structure, wherein at least a portion of the second well region is arranged in the absorption structure.

8. The device of claim 1, wherein the absorption structure comprises a first doped region having the first doping concentration, a second doped region having a second doping concentration of the first doping type, and a third doped region having a third doping concentration of the first doping type, wherein the second doped region is arranged between the first doped region and the third doped region, wherein the first, second, and third doping concentrations are different from one another, wherein the second doping concentration and the third doping concentration are greater than the doping concentration of the region of the substrate, wherein at least one of the first, second, and third doping concentrations is greater than approximately 2×10¹⁸ atoms/cm³.

9. The device of claim 8, wherein the first doping concentration is less than the second doping concentration and the third doping concentration is greater than the second doping concentration, wherein the first doped region occupies a first volume of the absorption structure and the second doped region occupies a second volume of the absorption structure less than the first volume.

10. The device of claim 1, further comprising:
a capping layer over a top surface of the absorption structure, wherein the capping layer comprises the second material and has the first doping type, wherein a doping concentration of the capping layer is greater than the first doping concentration.

11. A method, comprising:
forming a first well region in a substrate, wherein the substrate comprises silicon;
forming a second well region in the substrate and abutting the first well region; and
forming a germanium structure on a surface of the substrate, wherein the second well region is arranged between the first well region and the germanium structure, wherein the germanium structure and the second well region comprise a first doping type, wherein the first well region comprises a second doping type opposite the first doping type, wherein a doping concentration of the germanium structure is greater than doping concentrations of the first well region and the second well region.

12. The method of claim 11, wherein a dopant of the first doping type comprises boron or gallium, wherein the doping concentration of at least half a volume of the germanium structure is greater than approximately 2×10¹⁸ atoms/cm³, wherein a bulk of the substrate comprises the first doping type, wherein a doping concentration of the bulk of the substrate is less than the doping concentrations of the first well region and the second well region.

13. The method of claim 11, further comprising:
etching the substrate to form a recess in the substrate, wherein the recess is defined by opposing sidewalls and the surface of the substrate, wherein the germanium structure is formed in the recess and contacts the opposing sidewalls and the surface of the substrate.

14. The method of claim 13, wherein the first well region comprises a pair of segments disposed on opposing sides of the recess, wherein a bottom of the first well region is arranged above a bottom surface of the germanium structure, wherein the second well region is disposed laterally between the pair of segments of the first well region and the germanium structure.

15. The method of claim 11, further comprising:
forming a vertical connection region in the substrate and on opposing ends of the first well region, wherein the vertical connection region comprises the second doping type, wherein a bottom surface of the germanium structure is vertically above a top of the vertical connection region.

16. The method of claim 15, further comprising:
forming a germanium capping layer over a top surface and along opposing sidewalls of the germanium structure, wherein the germanium capping layer comprises the first doping type and has a doping concentration greater than the doping concentration of the germanium structure.

17. The method of claim 11, wherein the germanium structure comprises a first doped layer, a second doped layer over the first doped layer, and a third doped layer over the second doped layer, wherein the doping concentration of the germanium structure changes across the first, second, and third doped layers, wherein in cross-sectional view the first doped layer and the second doped layer are respectively U-shaped, wherein the second doped layer extends along opposing sidewalls and a lower surface of the third doped layer.

18. A method, comprising:
performing a first implantation process to form a lateral connection region in a substrate, wherein the substrate comprises a first material, wherein a bulk of the substrate comprises a first doping type and the lateral connection region comprises a second doping type opposite the first doping type;
performing a second implantation process to form a first contact region and a vertical connection region in the substrate, wherein the first contact region overlies the vertical connection region and the vertical connection region is on opposing sides of the lateral connection region, wherein the first contact region and the vertical connection region comprise the second doping type;
performing a third implantation process to form an avalanche well in the substrate and over the lateral connection region, wherein the avalanche well comprises the first doping type; and
forming an absorption structure on a surface of the substrate, wherein the absorption structure comprises a second material different from the first material, wherein the absorption structure comprises the first doping type and has a first doping concentration that is greater than approximately 2×10¹⁸ atoms/cm³.

19. The method of claim 18, wherein forming the absorption structure comprises:
forming a first doped layer over the substrate;
forming a second doped layer over the first doped layer; and
forming a third doped layer over the second doped layer, wherein one or more of the first, second, and third doped layers have the first doping concentration, wherein at least an individual one of the first, second, and third doped layers has a second doping concentration less than the first doping concentration.

20. The method of claim 19, further comprising:
etching the substrate to form a recess extending into the substrate, wherein the first doped layer lines opposing sidewalls and the surface of the substrate defining the recess, wherein the second doped layer is arranged along interior surfaces of the first doped layer, and the third doped layer is arranged along interior surfaces of the second doped layer.
